(19) United States
(12) Patent Application Publication
(10) Pub. No.: US 2025/0113624 A1
(43) Pub. Date: Apr. 3, 2025

(54) PHOTOELECTRIC CONVERSION DEVICE, PHOTOELECTRIC CONVERSION SYSTEM, MOBILE BODY, AND APPARATUS

(71) Applicant: CANON KABUSHIKI KAISHA, Tokyo (JP)

(72) Inventors: HIROSHI SEKINE, Kanagawa (JP); DAIKI SHIRAHIGE, Kanagawa (JP); KAZUHIRO MORIMOTO, Kanagawa (JP)

(21) Appl. No.: 18/882,053

(22) Filed: Sep. 11, 2024

(30) Foreign Application Priority Data
Sep. 29, 2023 (JP) 2023-169516

(51) Int. Cl. H01L 31/107; H01L 27/146; H01L 31/02

(52) U.S. Cl. CPC H10F 30/225; H10F 39/807; H10F 39/811; H10F 77/959

(57) ABSTRACT

A photoelectric conversion device according to the present invention includes a first pixel including a first avalanche photodiode, a second pixel including a second avalanche photodiode, and an isolating portion that isolates the first pixel and the second pixel, wherein in a plan view, a distance from a center of the first pixel to the isolating portion is longer than a distance from a center of the second pixel to the isolating portion.

### BACKGROUND

### Field

The present disclosure relates to a photoelectric conversion device, a photoelectric conversion system, a mobile body, and an apparatus.

### Description of the Related Art

A photoelectric conversion device that can detect a weak light in a single photon level by using avalanche multiplication is known. U.S. Patent Application Publication No. 2017/0186798 discloses a photoelectric conversion device electrically connecting both a sensor chip, on which a plurality of pixels are arrayed, and a circuit chip, on which circuits to perform signal processing are formed, by using a layered structure. It is also disclosed here that an avalanche photodiode (APD), in which electric charges cause avalanche multiplication, is used for the pixel in the sensor chip of this photoelectric conversion device.

Further, a technique using a high sensitivity pixel and a low sensitivity pixel to expand a dynamic range or to suppress flicker is also known. Japanese Patent Application Publication No. 2022-168741 discloses a light-receiving device using an APD for a high sensitivity pixel and a low sensitivity pixel respectively.

However in the configuration where the high sensitivity pixel and the low sensitivity pixel each include an APD, there is still room left to consider a more suitable structure of pixels.

### SUMMARY

The present invention in its first aspect provides a photoelectric conversion device including a first pixel including a first avalanche photodiode, a second pixel including a second avalanche photodiode, and an isolating portion that isolates the first pixel and the second pixel, wherein in a plan view, a distance from a center of the first pixel to the isolating portion is longer than a distance from a center of the second pixel to the isolating portion.

The present invention in its second aspect provides a photoelectric conversion device including a first pixel including a first avalanche photodiode, and a second pixel including a second avalanche photodiode, and being configured such that leakage of light from the first pixel to the second pixel is suppressed more strongly than leakage of light from the second pixel to the first pixel.

The present invention in its third aspect provides a photoelectric conversion device including a first pixel including a first avalanche photodiode, and a second pixel including a second avalanche photodiode, wherein a trench, which is not disposed in the second pixel, is disposed in the first pixel.

The present invention in its fourth aspect provides a photoelectric conversion system including the above-described photoelectric conversion device, and a signal processing unit which generates an image by using a signal outputted by the photoelectric conversion device.

The present invention in its fifth aspect provides a mobile body including the above-described photoelectric conversion device, the mobile body including a control unit which controls movement of the mobile body by using a signal outputted by the photoelectric conversion device.

The present invention in its sixth aspect provides an apparatus including the above-described photoelectric conversion device, and at least one of an optical device corresponding to the photoelectric conversion device, a control device that controls the photoelectric conversion device, a processing device that processes a signal outputted from the photoelectric conversion device, a display device that displays information acquired by the photoelectric conversion device, a storage device that stores information acquired by the photoelectric conversion device, and a mechanical device that operates based on information acquired by the photoelectric conversion device.

The present invention provides a suitable structure of pixels in a configuration where a high sensitivity pixel and a low sensitivity pixel include an avalanche photodiode respectively.

Further features of the present invention will become apparent from the following description of exemplary embodiments with reference to the attached drawings.

### BRIEF DESCRIPTION OF THE DRAWINGS

FIG. 1 is a schematic diagram of a photoelectric conversion device according to an embodiment;

FIG. 2 is a schematic diagram of a pixel substrate of the photoelectric conversion device according to an embodiment;

FIG. 3 is a schematic diagram of a circuit substrate of the photoelectric conversion device according to an embodiment;

FIGS. 4A and 4B are configuration examples of a pixel circuit of the photoelectric conversion device according to an embodiment;

FIG. 5 is a schematic diagram indicating driving of a pixel circuit of the photoelectric conversion device according to an embodiment;

FIG. 6A is a plan view of a photoelectric conversion device according to Embodiment 1;

FIG. 6B is a cross-sectional view of the photoelectric conversion device according to Embodiment 1;

FIG. 7A is a plan view of a photoelectric conversion device according to a comparative example;

FIG. 7B is a cross-sectional view of the photoelectric conversion device according to a comparative example;

FIG. 8 is a cross-sectional view of a modification of the photoelectric conversion device according to Embodiment 1;

FIG. 9A is a plan view of a photoelectric conversion device according to Embodiment 2;

FIG. 9B is a cross-sectional view of the photoelectric conversion device according to Embodiment 2;

FIGS. 10A to 10C are plan views of a photoelectric conversion device according to Embodiment 3;

FIGS. 11A and 11B are cross-sectional views of the photoelectric conversion device according to Embodiment 3;

FIGS. 12A to 12C are plan views of a photoelectric conversion device according to Embodiment 4;

FIGS. 13A and 13B are cross-sectional views of the photoelectric conversion device according to Embodiment 4;

FIGS. 14A to 14C are plan views of a photoelectric conversion device according to Embodiment 5;

FIGS. 15A to 15C are cross-sectional views of the photoelectric conversion device according to Embodiment 5;

FIGS. 16A to 16C are plan views of a photoelectric conversion device according to Embodiment 6;

FIGS. 17A to 17C are cross-sectional views of the photoelectric conversion device according to Embodiment 6;

FIG. 18 is a plan view of a photoelectric conversion device according to Embodiment 7;

FIGS. 19A to 19C are cross-sectional views of the photoelectric conversion device according to Embodiment 7;

FIG. 20 is a plan view of a modification of the photoelectric conversion device according to Embodiment 7;

FIGS. 21A and 21B are plan views of a photoelectric conversion device according to Embodiment 8;

FIGS. 22A to 22C are cross-sectional views of the photoelectric conversion device according to Embodiment 8;

FIG. 23 is a plan view of a photoelectric conversion device according to Embodiment 9;

FIGS. 24A to 24C are cross-sectional views of the photoelectric conversion device according to Embodiment 9;

FIG. 25 is a diagram for describing a photoelectric conversion system according to Embodiment 10;

FIG. 26A is a diagram for describing a photoelectric conversion system according to Embodiment 11;

FIG. 26B is a diagram for describing a mobile body according to Embodiment 11;

FIG. 27 is a diagram for describing a distance image sensor according to Embodiment 12;

FIG. 28 is a diagram for describing an endoscopic surgery system according to Embodiment 13;

FIGS. 29A and 29B are diagrams for describing smart glasses according to Embodiment 14;

FIGS. 30A and 30B are diagrams for describing an electronic apparatus according to Embodiment 15;

FIG. 31 is a diagram for describing an X-ray CT device according to Embodiment 16; and

FIG. 32 is a diagram for describing an apparatus according to Embodiment 17.

### DESCRIPTION OF THE EMBODIMENTS

The following embodiments are for carrying out the technical concept of the present invention, and do not limit the scope of the invention. The sizes and positional relationships of the members indicated in each drawing may be exaggerated to clarify the description. In the following description, same composing elements are denoted with a same reference number, and redundant description thereof may be omitted.

Embodiments of the present invention will now be described in detail with reference to the drawings. In the following description, terms to indicate a specific direction or position (e.g. “upper”, “lower”, “right”, “left” and the like) may be used when necessary. These terms are used to assist in understanding the embodiment with reference to the drawings, and are not intended to limit the technical scope of the present invention by the meaning of these terms.

In the present description, a “plan view” refers to a view in a direction that is vertical to a light incident surface of a semiconductor layer. And a “cross-sectional view” refers to a view of a section of the semiconductor layer that is vertical to the light incident surface. In a case where the light incident surface of the semiconductor layer is rough from a microscopic view, the plan view is defined based on the light incident surface of the semiconductor layer from a macroscopic view.

The semiconductor layer has a first surface and a second surface (surface on the opposite side of the first surface) to which light enters. In the present description, a depth direction is a direction from the first surface of the semiconductor layer, on which an avalanche photodiode (APD) is disposed, to the second surface. In the following, the “first surface” may be called a “front surface”, and the “second surface” may be called a “rear surface”. A “depth” at a point or a region of the semiconductor layer refers to a distance from the first surface (front surface) at the point or the region. In the case where Z1 is a point (or a region) of which distance (depth) from the first surface is d1, Z2 is a point (or a region) of which distance (depth) from the first surface is d2, and d1>d2 is established, it may be expressed that “Z1 is deeper than Z2”, or “Z2 is shallower than Z1”. Further, in a case where Z3 is a point (or a region) of which distance (depth) from the first surface is d3, and d1>d3>d2 is established, it may be expressed that “Z3 has a depth between Z1 and Z2”, or “Z3 is between Z1 and Z2 in the depth direction”.

In the following description, it is assumed that an anode of the avalanche photodiode (APD) has a fixed potential, and signals are extracted from a cathode side. Therefore a first conductivity type semiconductor region, where the electric charges having a polarity the same as a signal charge are majority carriers, is an N-type semiconductor region, and a second conductivity type semiconductor region, where the electric charges having a polarity different from the signal charge are majority carriers, is a P-type semiconductor region. The present invention is also established even in a case where the cathode of the APD has a fixed potential, and signals are extracted from the anode side. In this case, the first conductivity type semiconductor region, where the electric charges of a polarity the same as the signal charge are majority carriers, is a P-type semiconductor region, and the second conductivity type semiconductor region, where the charges having a polarity different from the signal charge are majority carriers, is the N-type semiconductor region. In the following description, one node of the APD has a fixed potential, but the potentials of both nodes may fluctuate.

In the present description, “impurity concentration” refers to the net impurity concentration obtained by subtracting the amount compensated for by the reverse conductive impurity. In other words, “impurity concentration” refers to the net doping concentration. A region, where the P-type added impurity concentration is higher than the N-type added impurity concentration, is a P-type semiconductor region. On the contrary, a region, where the N-type added impurity concentration is higher than the P-type added impurity concentration, is an N-type semiconductor region.

In the following embodiment, the interconnection of elements of a circuit may be stated. In this case, it is handled assuming that these elements are electrically interconnected, unless otherwise specified, even if other elements exist between these elements. For example, an element A is connected to one node of a capacitance element C which includes a plurality of nodes, and an element B is connected to another node. Even in this case, the element A and the element B are handled assuming that these elements are electrically interconnected unless otherwise stated. In a case where elements are interconnected without an intermediate element, it may be expressed that these elements are directly interconnected. In the above example, the element A and the capacitance element C can be said to be “directly interconnected” if no other element is disposed between the element A and the capacitance element C.

Metal members, such as wires and pads, in the present description may be constituted of a single element metal, or may be a mixture (alloy). For example, wires described as copper wires may be constituted of coper alone, or may be constituted mainly of copper with additional other elements. Further, pads connected with external terminals may be constituted of aluminum alone, or may be constituted mainly of aluminum with additional other elements, for example. The copper wires and aluminum pads described here are examples, and the materials may be changed to various other metals.

The wires and pads described here are examples of metal member used in the photoelectric conversion device, however other metal members may be used as well.

In each embodiment to be described below, mainly an imaging apparatus will be described as an image of the photoelectric conversion device. However, the application of each embodiment is not limited to an imaging apparatus, and there may be other examples of the photoelectric conversion device. For example, each embodiment is applicable to a distance measurement device (device for distance measurement using focal point detection or time of flight (ToF)), and a photometric device (e.g. device for measuring incident light quantity).

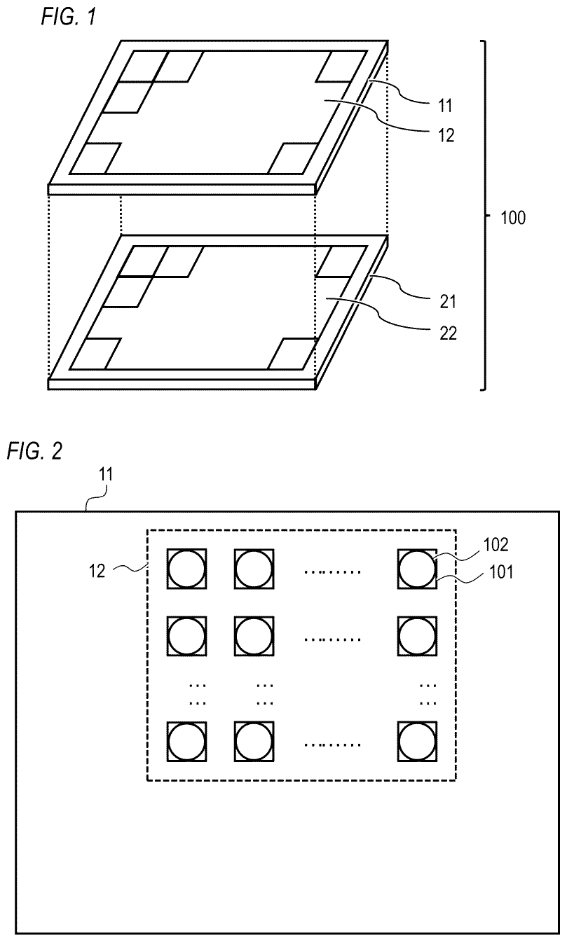

Configuration of the photoelectric conversion device according to the present invention and a driving method thereof, common to each embodiment, will be described with reference to FIGS. 1 to 5.

FIG. 1 is a diagram depicting a configuration of a photoelectric conversion device 100 according to an embodiment of the present invention. In the following, a case where the photoelectric conversion device 100 is a stacked type photoelectric conversion device will be described as an example. In other words, a photoelectric conversion device constituted of two substrates of a sensor substrate 11 and a circuit substrate 21, which are stacked and electrically connected, will be described as an example. However the photoelectric conversion device is not limited to this. For example, a photoelectric conversion device to be described below, where a configuration included in the sensor substrate 11 and a configured included in the circuit substrate 21 are disposed on a common semiconductor layer, may be used. In the following description, the photoelectric conversion device, where a configuration included in the sensor substrate 11 and a configuration included in the circuit substrate 21 are disposed on a common semiconductor layer, is also called an “unstacked type photoelectric conversion device”.

The sensor substrate 11 includes a first semiconductor layer, which has later mentioned photoelectric conversion elements 102, and a first wiring structure. The circuit substrate 21 includes a second semiconductor layer, which has such circuits as later mentioned signal processing units 103, and a second wiring structure. The photoelectric conversion device 100 is constituted of the second semiconductor layer, the second wiring structure, the first wiring structure, and the first semiconductor layer, which are layered in this sequence.

FIG. 1 indicates a back-side illuminated photoelectric conversion device where light enters through a second surface (rear surface), and the circuit substrate 21 is disposed on a first surface (front surface), which is a surface on the opposite side of the second surface. In the case of an unstacked photoelectric conversion device, a surface on the side where transistors of the signal processing circuits are disposed is called a “first surface”. In the case of a front-side illuminated photoelectric conversion device, the front surface is a second surface (light incident surface), and the rear surface is the first surface.

In the following description, the sensor substrate 11 and the circuit substrate 21 are diced chips, but are not limited to chips. For example, each substrate may be a wafer. Further, each substrate may be stacked in the waver state and then diced, or may be created as a chip first then each chip may be stacked by bonding.

A pixel region 12 is disposed on the sensor substrate 11, and a circuit region 22, to process a signal detected in the pixel region 12, is disposed on the circuit substrate 21.

FIG. 2 is a layout drawing of the sensor substrate 11. A pixel 101 having a photoelectric conversion element 102, including an avalanche photodiode (APD), is two-dimensionally arrayed so as to form the pixel region 12.

The pixel 101 is typically a pixel for forming an image, but when used for the time of flight (ToF) it may not form an image. In other words, the pixel 101 may be a pixel for measuring time and the quantity of light when the light arrives.

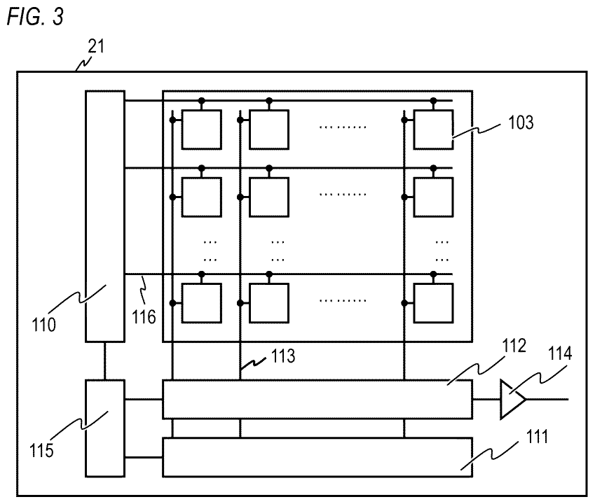

FIG. 3 is a block diagram of the circuit substrate 21. The circuit substrate 21 includes: the signal processing units 103 which process the electric charges generated by photoelectric conversion of the photoelectric conversion elements 102 in FIG. 2, a reading circuit 112, a control pulse generation unit 115, a horizontal scanning circuit unit 111, signal lines 113, a vertical scanning circuit unit 110, drive lines 116, and an output circuit 114.

Each of the photoelectric conversion elements 102 in FIG. 2 and each of the signal processing units 103 in FIG. 3 are electrically connected respectively via a connection wire disposed for each pixel.

The vertical scanning circuit unit 110 receives control pulses supplied from the control pulse generation unit 115, and supplies the control pulses to each pixel via the drive lines 116. For the vertical scanning circuit unit 110, a logic circuit, such as a shift register and an address decoder, is used.

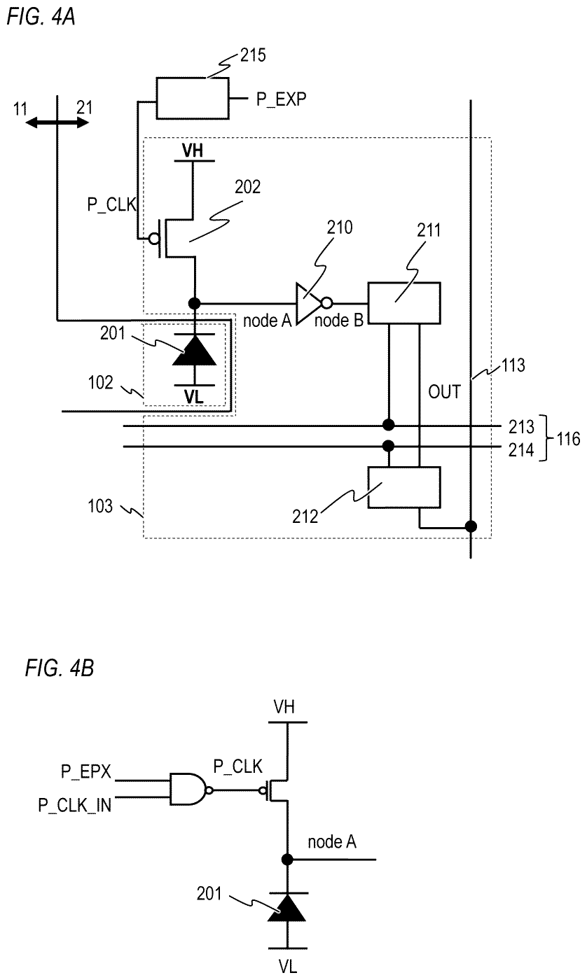

The control pulse generation unit 115 includes a later mentioned signal generation unit 215 which generates a control signal P_CLK of a later mentioned switch. The signal generation unit 215 generates pulse signals to control the switch, as described later. For example, as indicated in FIG. 4A, the signal generation unit 215 may generate a common control signal P_CLK for a plurality of pixels of the pixel region 12, or as indicated in FIG. 4B, the signal generation unit 215 may generate a control signal P_CLK for each pixel. In the case of generating the common control signal P_CLK, the common signal is generated such that at least one of: the cycle, number of pulses, and pulse width of a signal P_EXP (pulse signal), to control the exposure period, is corresponded to the exposure period. In the case of controlling the control signal P_CLK for each pixel, the signal is generated using both the input signal P_CLK_IN outputted from the control pulse generation unit 115 and a signal P_EXP to control the exposure period. It is preferable that the control pulse generation unit 115 includes a divider circuit, for example. Then simple control becomes possible, and an increase in a number of elements can be prevented.

The signal outputted from the photoelectric conversion element 102 in each pixel is processed by the signal processing unit 103. In the signal processing unit 103, a counter, a memory, and the like are disposed, and a digital value is held in the memory.

The horizontal scanning circuit unit 111 inputs a control pulse, which sequentially selects each column, to the signal processing unit 103, in order to read a signal from the memory of each pixel in which the digital signal is held.

A signal is outputted to the signal line 113 from the signal processing unit 103 of a pixel selected by the vertical scanning circuit unit 110 for a selected column.

The signal outputted to the signal line 113 is outputted to a recording unit or a signal processing unit outside the photoelectric conversion device 100 via the output circuit 114.

In FIG. 2, the array of the pixels 101 in the pixel region 12 may be disposed one-dimensionally. The function of the signal processing unit 103 need not be disposed for each of the pixels 101 on a one-to-one basis, but one signal processing unit 103 may be shared by a plurality of pixels 101, for example, and the signal processing is sequentially performed for each pixel 101.

FIGS. 4A and 4B are examples of the block diagrams, including the equivalent circuits of FIGS. 2 and 3. FIG. 4A is an example where a common signal generation unit 215 is disposed for a plurality of pixels, and FIG. 4B is an example where the control signal P_CLK can be controlled for each pixel. FIG. 4A will be described here.

In FIG. 4A, the photoelectric conversion element 102, which includes an APD 201, is disposed on the sensor substrate 11, and the other members are disposed on the circuit substrate 21.

The APD 201 generates an electric charge pair in accordance with the incident light by the photoelectric conversion. Voltage VL (first voltage) is supplied to an anode of the APD 201. Voltage VH (second voltage), which is higher than the voltage VL supplied to the anode, is supplied to a cathode of the APD 201. To the anode and the cathode, a reverse bias voltage is supplied so that the APD 201 performs the avalanche multiplication operation. By supplying such voltage, the electric charges generated by the incident light causes the avalanche multiplication, whereby avalanche current is generated.

Reverse bias voltage is supplied either in Geiger mode, in which potential difference of the anode and the cathode during operation is larger than the breakdown voltage, or in linear mode, in which the potential difference of the anode and the cathode during operation is about the same or less than the breakdown voltage. An APD which operates in the Geiger mode is called SPAD. For example, the voltage VL (first voltage) is −30V, and the voltage VH (second voltage) is 1V. The APD 201 may be operated in the linear mode or in the Geiger mode. In the case of SPAD, potential difference is larger than the APD operated in the linear mode, and the effect of high withstand voltage becomes remarkable.

A switch 202 is connected to a power line to which the drive voltage VH is supplied, and the APD 201. The switch 202 is connected to one of the anode and the cathode of the APD 201. Then the switch 202 switches the potential difference between the anode and the cathode of the APD 201, between the first potential difference at which the avalanche multiplication is generated and a second potential difference at which the avalanche multiplication is not generated. In the following description, switching from the second potential difference to the first potential difference is also called “turning ON” the switch 202, and switching from the first potential difference to the second potential difference is also called “turning OFF” the switch 202. The switch 202 functions as a quench element. The switch 202 functions as a load circuit (quench circuit) when the signals are multiplied by the avalanche multiplication, and performs the function to suppress the avalanche multiplication (quench operation) by suppressing the voltage supplied to the APD 201. The switch 202 also has a function to return the voltage supplied to the APD 201 back to the drive voltage VH (recharge operation) by supplying current for an amount causing a drop of the voltage in the quench operation. In other words, the switch 202 functions as a control circuit that controls the generation of the avalanche multiplication in the APD 201.

The switch 202 can be constituted of an MOS transistor, for example. A control signal P_CLK of the switch 202, supplied from the signal generation unit 215, is applied to a gate electrode of the MOS transistor constituting the switch 202. In the present embodiment, the ON or OFF of the switch 202 is controlled by controlling the applied voltage to the gate electrode of the switch 202.

The signal processing unit 103 includes a waveform shaping unit 210, a counter circuit 211, and a selection circuit 212. In the present description, it is sufficient if the signal processing unit 103 includes at least one of the waveform shaping unit 210, the counter circuit 211, and the selection circuit 212.

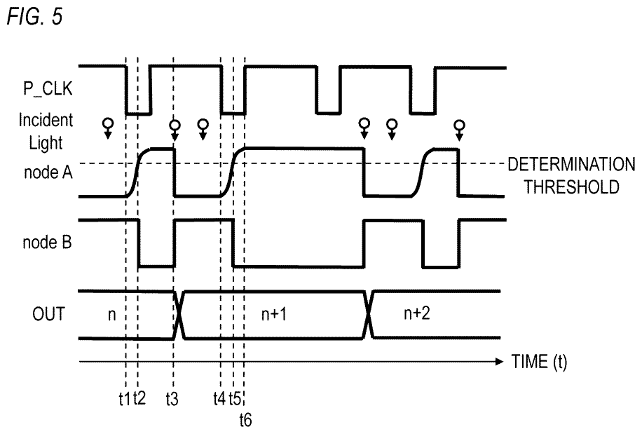

The waveform shaping unit 210 shapes the potential change of the cathode of the APD 201 acquired when photons are detected, and outputs pulse signals. It is assumed that a node on the input side of the waveform shaping unit 210 is node A, and a node on the output side thereof is node B. The waveform shaping unit 210 changes the output potential from the node B, depending on whether the input potential to node A is at least a predetermined value or lower than the predetermined value. For example, if the input potential to node A is at least the potential of the determination threshold in FIG. 5, the output potential from node B becomes a low level. If the input potential to node A is lower than the determination threshold, the output potential from node B becomes a high level. For the waveform shaping unit 210, an inverter circuit, for example, is used. In the example of FIG. 4A, one inverter is used for the waveform shaping unit 210, but a circuit in which a plurality of inverters are connected in series may be used, or other circuits which generate the waveform shaping effect may be used.

The quench operation and the recharge operation can be performed using the switch 202 in accordance with the avalanche multiplication in the APD 201, but in some cases the electric charges generated in the APD 201 may not be determined as an output signal, depending on the photon detection timing. For example, it is assumed that the avalanche multiplication is generated in the APD 201, and node A becomes a low level, and the recharge operation is performed. Generally the determination threshold of the waveform shaping unit 210 is set to a potential higher than the potential difference with which the avalanche multiplication is generated in the APD 201. If the recharge operation is performed and photons enter the APD 201 when the potential of node A is lower than the determination threshold, and the potential is a potential with which the avalanche multiplication in the APD 201 is possible, the avalanche multiplication is generated in the APD 201, and the voltage in node A drops. In other words, the potential of node A drops at a voltage lower than the determination threshold, hence the potential change crossing over the determination threshold is not generated, and the output potential from node B does not change. This means that the detection of the photons is not determined as a signal, even though the avalanche multiplication was generated. Particularly under high luminance, the photons continuously enter the APD 201 in a short period of time, hence the incident light is not always determined as a signal. As a result, an actual number of entered photons and outputted signals tend to diverge, even if luminance is high.

If the ON or OFF of the switch 202 is switched by applying the control signal P_CLK to the switch 202, on the other hand, a signal can be determined even if the photons continuously enter the APD 201 in a short period of time. In FIG. 5, an example where the control signal P_CLK is a pulse signal with a repeating cycle will be described. In other words, in FIG. 5, a case of switching the ON or OFF of the switch 202 at a predetermined clock frequency will be described. The effect of suppressing an increase in power consumption of the photoelectric conversion device 100, however, can still be acquired, even if the pulse signal is not a signal with a repeating cycle.

The counter circuit 211 counts pulse signals outputted from the waveform shaping unit 210, and holds the count value. When a control pulse pRES is supplied via a drive line 213, the count value of the signals that are held in the counter circuit 211 is reset.

A control pulse pSEL is supplied to the selection circuit 212 from the vertical scanning circuit unit 110 in FIG. 3 via a drive line 214 in FIG. 4A, and switches the electrical connection or disconnection between the counter circuit 211 and the signal line 113. The selection circuit 212 includes a buffer circuit to output signals, for example.

The electrical connection or disconnection may be switched by disposing a switch (e.g. transistor) between the switch 202 and the APD 201, or between the photoelectric conversion element 102 and the signal processing unit 103. In the same manner, supply of the voltage VH or the voltage VL to the photoelectric conversion element 102 may be electrically switched using a switch (e.g. transistor).

In the configuration described in the present embodiment, the counter circuit 211 is used. However instead of the counter circuit 211, a time to digital converter (hereafter TDC) may be used, or the photoelectric conversion device 100 may acquire the pulse detection timing using a memory. In this case, the generation timing of the pulse signal outputted from the waveform shaping unit 210 is converted to a digital signal by the TDC. In order to measure the timing of the pulse signal, a control pulse pREF (reference signal) is supplied to the TDC from the vertical scanning circuit unit 110 in FIG. 3 via the drive line. The TDC acquires, as a digital signal, a value determined, with the input timing of the signal that is outputted from each pixel being a relative time based on the control pulse PREF.

FIG. 5 is a schematic diagram depicting the relationship of the control signal P_CLK of the switch, the potential of node A, the potential of node B, and the output signal. In the present embodiment, when the control signal P_CLK is at the high level, supply of the drive voltage VH to the APD 201 is interrupted, and when the control signal P_CLK is at the low level, the drive voltage VH is supplied to the APD 201. The high level of the control signal P_CLK is 1V, for example, and the low level of the control signal P_CLK is 0V, for example. When the control signal P_CLK is at the high level, the switch is turned OFF, and when the control signal P_CLK is at the low level, the switch is turned ON. A resistance value of the switch when the control signal P_CLK is at the high level is higher than a resistance value of the switch when the control signal P_CLK is at the low level. In the case where the control signal P_CLK is at the high level, the recharge operation is difficult to perform even if the avalanche multiplication is generated in the APD 201, hence the potential to be supplied to the APD 201 becomes the breakdown voltage of the APD 201 or less. As a consequence, the avalanche multiplication operation in the APD 201 stops.

As indicated in FIG. 4A, it is preferable that the switch 202 is constituted of one transistor, and the one transistor performs the quench operation and the recharge operation. Thereby a number of circuits can be decreased compared with the case of performing the quench operation and the recharge operation by different circuit elements respectively. Particularly in a case where each pixel has a counter circuit and the signal of the SPAD is read for each pixel, it is preferable to reduce the circuit area used for the switch to dispose the counter circuit, hence the effect of constituting the switch 202 with one transistor becomes remarkable.

At time t1, the control signal P_CLK changes from the high level to the low level, whereby the switch is turned ON and the recharge operation is started in the APD 201. Thereby the potential of the cathode of the APD 201 changes to the high level. Then the potential difference of the potentials applied to the anode and the cathode of the APD 201 becomes a state in which the avalanche multiplication can be performed. The potential of the cathode is the same as node A. Hence when the potential of the cathode changes from the low level to the high level, the potential of the node A becomes the determination threshold or more at time t2. At this timing, the pulse signal to be outputted from node B is inverted, and changes from the high level to the low level. Then in the APD 201, the pulse signal enters the state where the potential difference between the drive voltage VH and the drive voltage VL is applied. The control signal P_CLK becomes high level, and the switch is turned OFF.

Then when photons enter the APD 201 at time t3, the avalanche multiplication is generated in the APD 201, and the voltage of the cathode drops. In other words, the voltage of node A drops. As the voltage drop amount further increases and the voltage difference that is applied to the APD 201 decreases, the avalanche multiplication in the APD 201 stops at time t2, and the voltage level of node A does not drop exceeding a predetermined value. When the voltage of node A becomes lower than the determination threshold in the process of the voltage of node A dropping, the voltage of node B changes from the low level to the high level. In other words, a portion of the output waveform exceeding the determination threshold in node A is shaped by the waveform shaping unit 210, and is outputted as a signal from node B. Then the count value of the counter signals, which are counted by the counter circuit and outputted from the counter circuit, increases by 1LSB.

Photons enter the APD 201 between time t3 and time t4, but this is a period when the switch is OFF, and the applied voltage to the APD 201 has no potential difference to cause the avalanche multiplication, hence the voltage level of node A does not exceed the determination threshold.

At time t4, the control signal P_CLK changes from the high level to the low level, whereby the switch is turned ON. Because of this change, current to compensate for the amount of the voltage that dropped from the drive voltage VH flows to node A, and the voltage of node A changes to the original voltage level. Here the voltage of node A becomes the determination threshold or more at time t5, hence the pulse signal of node B is inverted and changes from the high level to the low level.

At time t6, node A is stabilized to the original voltage level, and the control signal P_CLK changes from the low level to the high level. Thereby the switch is turned OFF. Hereafter as described for time t1 to time t6, the potential of each node, signal line, and the like changes in accordance with the control signal P_CLK and the entry of photons.

In the following, a photoelectric conversion device according to each embodiment will be described.

### Embodiment 1

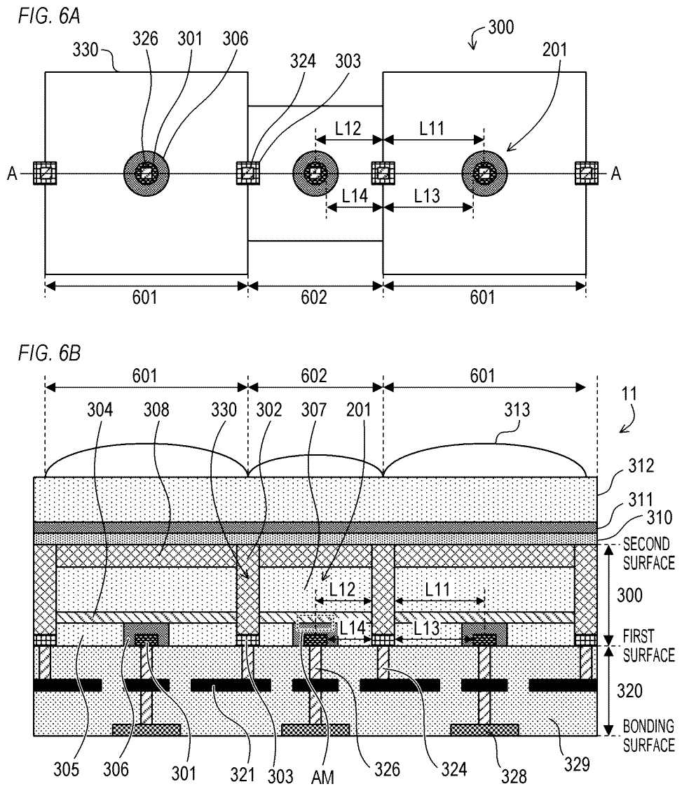

FIGS. 6A and 6B indicate a structure of the sensor substrate 11 of a photoelectric conversion device according to Embodiment 1. FIG. 6A is a plan view depicting a configuration of a pixel region 12, and is a schematic diagram viewing a semiconductor layer 300 of the sensor substrate 11 from the first surface side. FIG. 6B is a cross-sectional view sectioned at the A-A line in FIG. 6A.

As indicated in FIG. 6A, a plurality of APDs 201 are disposed on the semiconductor layer 300. In FIG. 6A, only three APDs 201 in one row×three columns are depicted to simplify illustration, but in an actual product, several hundred thousand to several million APDs 201 are formed in a two-dimensional array. One APD 201 corresponds to one pixel.

In the semiconductor layer 300, an isolating portion 330, which is an isolating structure to reduce optical crosstalk (light leakage) between adjacent APDs 201, is disposed. In FIG. 6A, the isolating portion 330 is drawn as a line, but actually the isolating portion 330 has thickness. An APD 201 is disposed in each section partitioned by this isolating portion 330. Thereby a plurality of pixels are isolated by the isolating portions 330. The section corresponding to one pixel has an approximately (substantially) square shape in a plan view. In other words, in a plan view, this isolating portion 330 surrounds one pixel in an approximately square shape. A contact plug 326 of a cathode wiring formed in a wiring structure 320 is disposed approximately at the center of the pixel (section), and a contact plug 324 of an anode wiring is disposed on an edge of the pixel.

As indicated in FIG. 6B, the sensor substrate 11 has a structure in which the semiconductor layer 300 and the wiring structure 320 are layered. A surface of the semiconductor layer 300 on the side of the wiring structure 320 is called a “first surface”, and a surface thereof on the opposite side of the first surface is called a “second surface”. The semiconductor layer 300 is constituted of silicon, for example. A fixed charge film 310, an insulating film 311, a planarizing film 312 and the like are sequentially layered on the second surface of the semiconductor layer 300, and a micro-lens 313 corresponding to each pixel, is disposed above these films. In other words, the photoelectric conversion device according to Embodiment 1 has a backside illuminated structure, where light enters the semiconductor layer 300 from the second surface side. The second surface is also called a “light incident surface”. For the light incident surface, the following structure may be used. For example, an uneven structure having at least one concave portion or convex portion is disposed on the second surface (light incident surface). The uneven structure is structured by silicon constituting the semiconductor layer 300 and other members. For example, such insulators as silicon oxide film, silicon oxynitride film, or a silicon nitride film is disposed in a concave portion formed in the semiconductor layer 300. Thereby an interface, which is not parallel with the second surface and has a refractive index difference, is formed. By this configuration, the incident light is diffracted, whereby sensitivity to light in the infrared region can be improved.

The fixed charge film 310 is constituted of dielectric material having negative fixed charges, and is disposed on the entire second surface of the semiconductor layer 300. The material of the fixed charge film 310 is selected from: hafnium oxide, aluminum oxide, zirconium oxide, titanium oxide, tantalum oxide, and ruthenium oxide, for example, and aluminum oxide or hafnium oxide is especially preferable. The fixed charge film 310 may be constituted of a plurality of layers. The insulating film 311 is disposed on the fixed charge film 310, so as to cover the entire second surface. For the insulating film 311, a silicon oxide film, a silicon oxynitride film or a silicon nitride film can be suitably used. The insulating film 311 may be constituted of a plurality of layers. In addition to the planarizing film 312, a filter layer of color filters or an infrared cut filter (not illustrated) may be disposed on the second surface side of the semiconductor layer 300.

The wiring structure 320 is a structure in which the wiring 321, the contact plugs 324 for the anode wiring, the contact plugs 326 for the cathode wiring, and the like are disposed in the insulating layer 329. The surface on the lower side (opposite aide of the semiconductor layer 300) of the wiring structure 320 is a bonding surface with the circuit substrate 21, and a plurality of bonding portions 328 (metal bondings) are disposed on the bonding surface.

The semiconductor layer 300 includes a first semiconductor region 301, a second semiconductor region 302, a third semiconductor region 303, a fourth semiconductor region 304, a fifth semiconductor region 305, a sixth semiconductor region 306, a seventh semiconductor region 307, and an eighth semiconductor region 308. Each of these semiconductor regions is a region in which impurities are added by ion implantation, or a region in which impurities are added when the semiconductor substrate is formed by epitaxial growth. Here the first semiconductor region 301, the fifth semiconductor region 305, the sixth semiconductor region 306, and the seventh semiconductor region 307 are first conductivity type (N-type in Embodiment 1) semiconductor regions. The second semiconductor region 302, the third semiconductor region 303, the fourth semiconductor region 304 and the eighth semiconductor region 308 are second conductivity type (P-type in Embodiment 1) semiconductor regions.

The first semiconductor region 301 is a first conductivity type (N-type in Embodiment 1) semiconductor region, and is disposed on the first surface of the semiconductor layer 300. The first semiconductor region 301 is formed in a circular shape at the center of the pixel (section) in the plan view, as indicated in FIG. 6A. The contact plug 326 of the cathode is connected to the center position of the first semiconductor region 301.

The fourth semiconductor region 304 is a second conductivity type (P-type in Embodiment 1) semiconductor region, and is disposed on the light-entering side (side closer to the second surface) of the first semiconductor region 301. The fourth semiconductor region 304 is formed in a layer form at a predetermined depth such that the first conductivity type epitaxial layer in one pixel (section) is separated into upper and lower portions. The periphery of the fourth semiconductor region 304 contacts with the isolating portion 330 which surrounds the pixel. The first conductivity type epitaxial layer on the first surface side of the fourth semiconductor region 304 is the fifth semiconductor region 305, and the first conductivity type epitaxial layer on the second surface side thereof is the seventh semiconductor region 307.

The first conductivity type first semiconductor region 301 and the second conductivity type fourth semiconductor region 304 form an avalanche multiplication portion AM by a PN junction. The signal charges generated in the seventh semiconductor region 307 by the photoelectric conversion are collected in the avalanche multiplication portion AM. In order to improve sensitivity of the pixel (APD 201), it is preferable to increase the size of the seventh semiconductor region 307 corresponding to the sensitivity region.

The sixth semiconductor region 306 has a first conductivity type semiconductor region formed around the first semiconductor region 301. The sixth semiconductor region 306 is also formed in a circular shape in the plan view. Here the impurity concentrations of the first semiconductor region 301, the sixth semiconductor region 306 and the fifth semiconductor region 305 are set to satisfy the relationship of the first semiconductor region 301>the sixth semiconductor region 306>the fifth semiconductor region 305. In other words, the impurity concentration of the first semiconductor region 301 is set highest, and the impurity concentration of the sixth semiconductor region 306 is set to be between the concentration of the first semiconductor region 301 and the concentration of the fifth semiconductor region 305. Thereby electric connection between the cathode and the first semiconductor region 301 (that is, APD 201) can be ensured. The sixth semiconductor region 306 plays a role of a guard ring for relaxing the electric field.

The eighth semiconductor region 308 is a second conductivity type buried layer that is disposed to constitute a part of the second surface of the semiconductor layer 300. The periphery of the eighth semiconductor region 308 contacts with the isolating portion 330, which surrounds the pixel. Th eighth semiconductor region 308 plays a role of suppressing noise from the second surface side. Further, voltage VL from the anode wiring can be supplied to the eighth semiconductor region 308 via the second semiconductor region 302. In this case, the potential gradient for collecting electric charges can be formed.

The isolating portion 330 is formed by the second conductivity type second semiconductor region 302, and prevents the transfer of electrons between the pixels using a potential barrier. The isolating portion 330 also constitutes a part of the second surface of the semiconductor layer 300.

The third semiconductor region 303, which is a connecting portion to electrically connect the contact plug 324 of the anode wiring and the second semiconductor region 302 of the isolating portion 330, is disposed on the first surface of the semiconductor layer 300. The second semiconductor region 302 and the third semiconductor region 303 are both second conductivity types (P-type in Embodiment 1).

As indicated in FIG. 6A, the third semiconductor region 303 is disposed on a portion corresponding to the contact plug 324. In an area other than the third semiconductor region 303, the second conductivity type semiconductor region is not exposed on the first surface.

As indicated in FIG. 6B, the shape of the micro-lens 313 is different between pixels 601 on both ends and the pixel 602 at the center. Because of this difference in shape, the sensitivity of the pixels 601 and the sensitivity of the pixel 602 are different. The pixel 601 is a high sensitivity pixel having a sensitivity higher than the sensitivity of the pixel 602, and the pixel 602 is a low sensitivity pixel having a sensitivity lower than the sensitivity of the pixel 601.

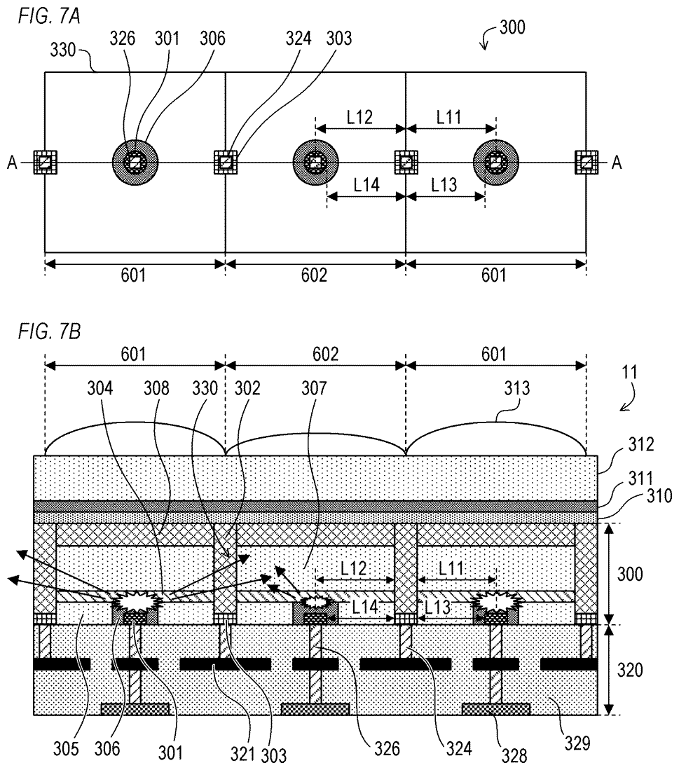

FIGS. 7A and 7B indicate a structure of the sensor substrate 11 of a photoelectric conversion device according to a comparative example. FIG. 7A is a plan view depicting a configuration of the pixel region 12, and is a schematic diagram viewing the semiconductor layer 300 of the sensor substrate 11 from the first surface side. FIG. 7B is a cross-sectional view thereof sectioned at the A-A line in FIG. 7A. As FIGS. 6A, 6B, 7A and 7B indicate, the basic configuration of the sensor substrate 11 of the comparative example is the same as that of the sensor substrate 11 according to Embodiment 1.

As indicated in FIGS. 7A and 7B, in the comparative example, the size of the high sensitivity pixel 601 and the size of the low sensitivity pixel 602 are the same. Therefore a degree of suppressing the optical crosstalk (light leakage) from the high sensitivity pixel 601 to the low sensitivity pixel 602 and a degree of suppressing the optical crosstalk from the low sensitivity pixel 602 to the high sensitivity pixel 601 are the same. In the high sensitivity pixel 601, the avalanche multiplication (avalanche emission) is generated more strongly compared with the low sensitivity pixel 602. Hence the optical crosstalk from the high sensitivity pixel 601 to the low sensitivity pixel 602 becomes larger than the optical crosstalk from the low sensitivity pixel 602 to the high sensitivity pixel 601.

Therefore in Embodiment 1, the optical crosstalk (light leakage) from the high sensitivity pixel 601 to the low sensitivity pixel 602 is suppressed more strongly than the optical crosstalk from the low sensitivity pixel 602 to the high sensitivity pixel 601. Specifically, as indicated in FIGS. 6A and 6B, the size of the low sensitivity pixel 602 is smaller than the high sensitivity pixel 601 (the size of the high sensitivity pixel 601 is larger than the low sensitivity pixel 602). More precisely, the following Condition 1-1 is satisfied.

Condition 1-1: In the plan view, the distance L11 from the center of the high sensitivity pixel 601 to the isolating portion 330 is longer than the distance L12 from the center of the low sensitivity pixel 602 to the isolating portion 330.

Further, in Embodiment 1, the following Condition 1-2 is also satisfied.

Condition 1-2: In the plan view, the distance L13 is longer than the distance L14. Here the distance L13 is a distance from an edge of the high sensitivity pixel 601 on the side of the isolating portion 330 of the first semiconductor region 301 (isolating portion side) to the isolating portion 330. The distance L14 is a distance from an edge of the low sensitivity pixel 602 on the side of the isolating portion 330 of the first semiconductor region 301 to the isolating portion 330.

By satisfying Condition 1-1 (and Condition 1-2), the distance from the avalanche multiplication portion AM of the high sensitivity pixel 601 to the isolating portion 330 becomes longer than the distance from the avalanche multiplication portion AM of the low sensitivity pixel 602 to the isolating portion 330. Thereby the optical crosstalk (light leakage) from the high sensitivity pixel 601 to the low sensitivity pixel 602 is suppressed more strongly than the optical crosstalk from the low sensitivity pixel 602 to the high sensitivity pixel 601. As a result, dispersion of the optical crosstalk (light leakage) among pixels can be reduced. Specifically, the difference between the optical crosstalk from the high sensitivity pixel 601 to the low sensitivity pixel 602 and the optical crosstalk from the low sensitivity pixel 602 to the high sensitivity pixel 601 can be reduced.

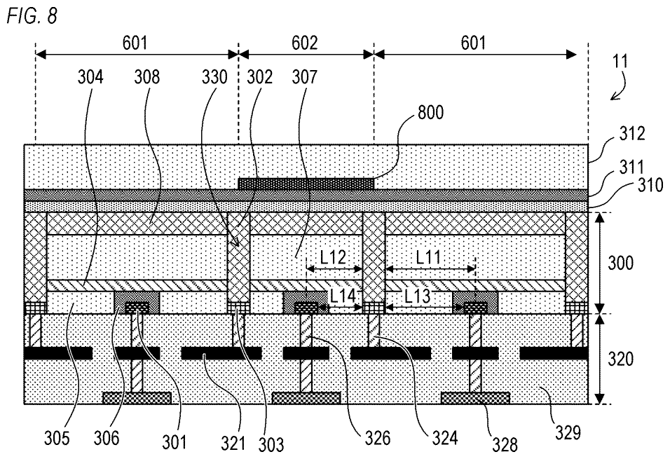

An example of changing the sensitivity of the pixel by changing the shape of the micro-lens 313 was described above, but the method for changing the sensitivity is not limited to this. For example, the sensitivity of the pixel may be reduced by using a light-shielding filter 800, as indicated in FIG. 8.

### Embodiment 2

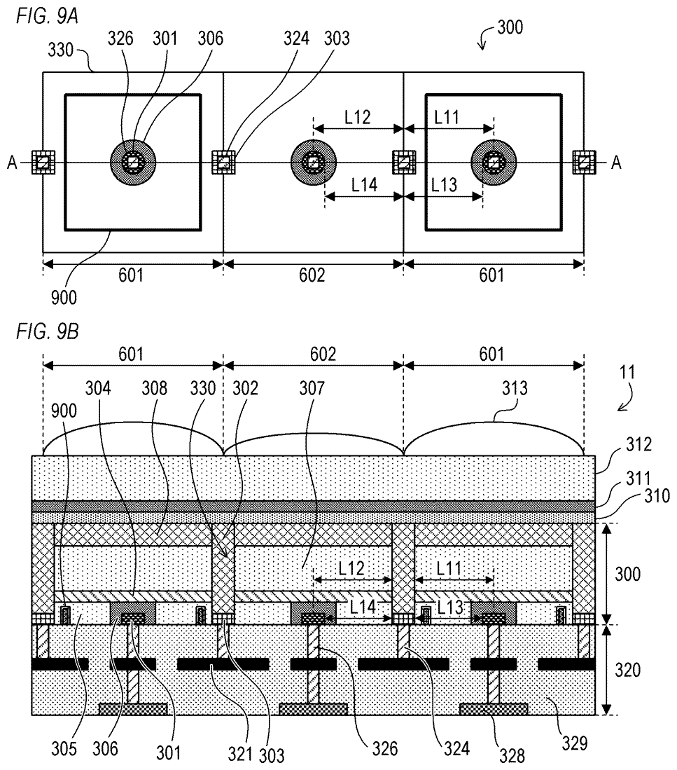

FIGS. 9A and 9B indicate a structure of the sensor substrate 11 of a photoelectric conversion device according to Embodiment 2. FIG. 9A is a plan view depicting a configuration of the pixel region 12, and is a schematic diagram viewing the semiconductor layer 300 of the sensor substrate 11 from the first surface side. FIG. 9B is a cross-sectional view sectioned at the A-A line in FIG. 9A. In the following, a configuration that is different from Embodiment 1 will be described.

In Embodiment 1, the size of the low sensitivity pixel 602 is smaller than the size of the high sensitivity pixel 601 (the size of the high sensitivity pixel 601 is larger than the size of the low sensitivity pixel 602). In Embodiment 2, a trench 900, which is not disposed in the low sensitivity pixel 602, is disposed in the high sensitivity pixel 601, as indicated in FIGS. 9A and 9B. In the plan view, the trench 900 surrounds the first semiconductor region 301 and the sixth semiconductor region 306. The trench 900 is formed at a depth (in the depth direction from the first surface) shallower than the fourth semiconductor region 304.

In Embodiment 2, the size of the high sensitivity pixel 601 and the size of the low sensitivity pixel 602 are the same, and the Conditions 1-1 and 1-2 of Embodiment 1 are not satisfied. However because of the trench 900 formed in the high sensitivity pixel 601, the optical crosstalk (light leakage) from the high sensitivity pixel 601 is suppressed more strongly. As a result, a difference between the optical crosstalk from the high sensitivity pixel 601 to the low sensitivity pixel 602 and the optical crosstalk from the low sensitivity pixel 602 to the high sensitivity pixel 601 can be reduced.

The trench 900 may have a deep trench isolation (DTI) structure, and a metal may be buried in the DTI structure to improve the light-shielding performance. The trench 900 may be constituted of an insulating film, a metal member, a fixed charge film, polysilicon, or a combination of a plurality of these members.

### Embodiment 3

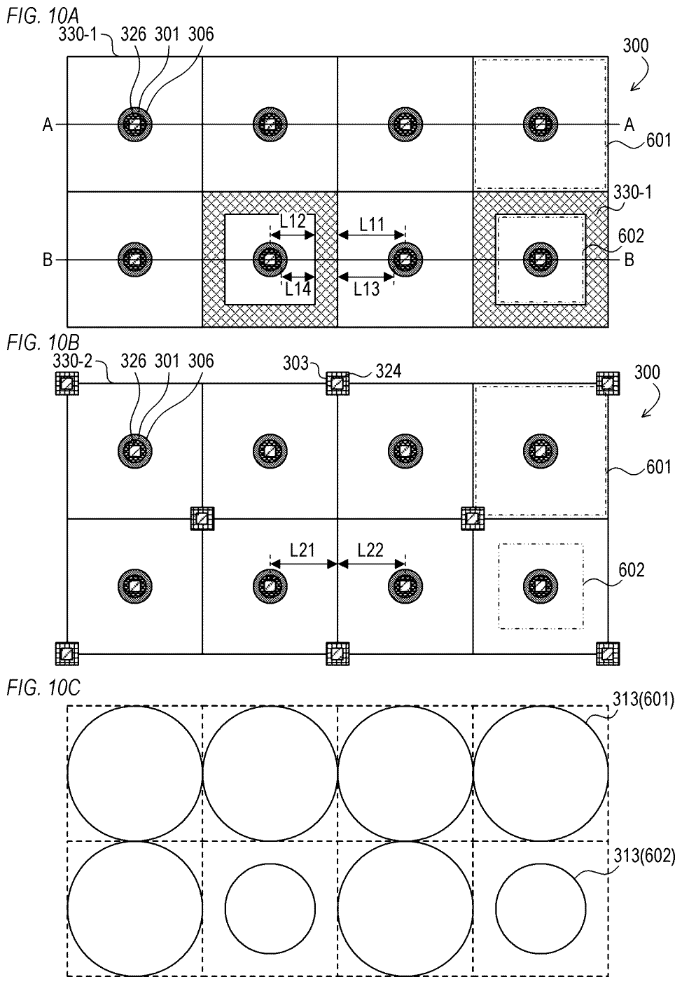

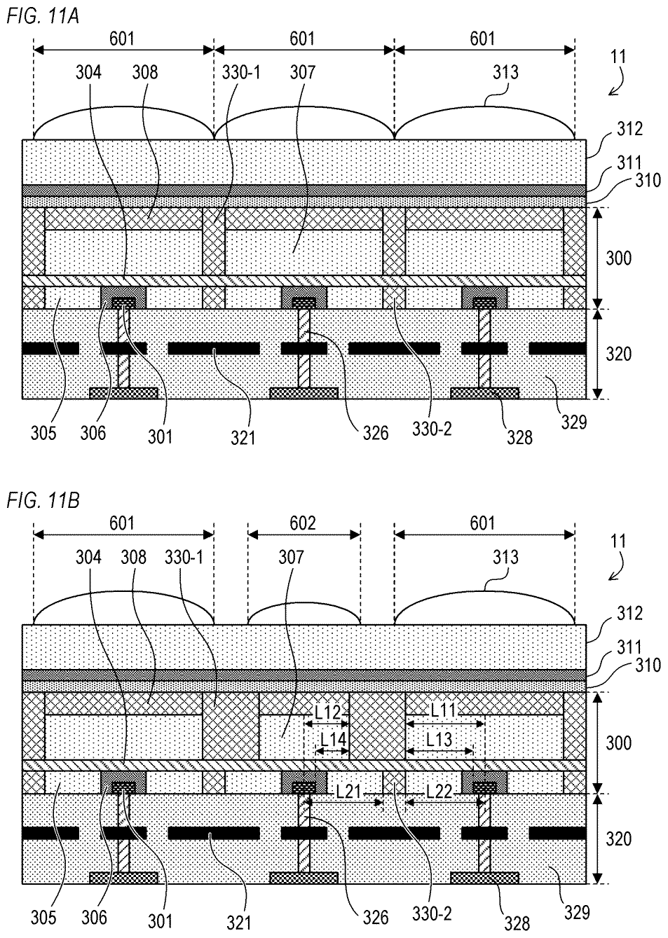

FIGS. 10A to 10C, 11A and 11B indicate a structure of the sensor substrate 11 of a photoelectric conversion device according to Embodiment 3. FIGS. 10A to 10C are plan views depicting a configuration of the pixel region 12. FIGS. 10A and 10B are schematic diagrams viewing the semiconductor layer 300 of the sensor substrate 11 from the first surface side, and FIG. 10C is a schematic diagram indicating an arrangement of the micro-lenses 313. FIG. 11A is a cross-sectional view sectioned at the A-A line in FIG. 10A, and FIG. 11B is a cross-sectional view sectioned at the B-B line in FIG. 10A. In the following, a configuration that is different from Embodiment 1 will be described.

In Embodiment 1, the size of the low sensitivity pixel 602 is smaller than the size of the high sensitivity pixel 601 (the size of the high sensitivity pixel 601 is larger than the size of the low sensitivity pixel 602). However in the smaller low sensitivity pixel 602, the anode electrode (contact plug 324) supplies anode potential to a semiconductor region constituting the isolating portion 330. Further, the cathode electrode (contact plug 326) supplies cathode potential to the first semiconductor region 301. Therefore the distance between the semiconductor region constituting the isolating portion 330 to which the anode potential is supplied and the first semiconductor region 301 to which the cathode potential is supplied becomes short, and noise caused by the electric field between these electrodes may increase.

In Embodiment 3, a first isolating portion 330-1 and a second isolating portion 330-2 are disposed as the isolating portions to isolate a plurality of pixels, as indicated in FIGS. 11A and 11B. FIG. 10A indicates an arrangement of the first isolating portion 330-1, the contact plug 326 of the cathode, and the like, and FIG. 10B indicates an arrangement of the second isolating portion 330-2, the contact plug 324 of the anode, the contact plug 326 of the cathode, and the like.

The first isolating portion 330-1 isolates each region of a plurality of pixels on a side closer to the second surface (light incident surface). Specifically, the first isolating portion 330-1 isolates each region of a plurality of pixels on the second surface side of the fourth semiconductor region 304. The first isolating portion 330-1 corresponds to the isolating portion 330 of Embodiment 1. The second isolating portion 330-2 isolates each region of a plurality of pixels on the side distant from the second surface. Specifically, the second isolating portion 330-2 isolates each region of a plurality of pixels on the first surface side of the fourth semiconductor region 304. The first isolating portion 330-1 and the second isolating portion 330-2 are both formed by second conductivity type semiconductor regions.

As indicated in FIG. 10A, the first isolating portion 330-1 is formed such that the Conditions 1-1 and 1-2 in Embodiment 1 are satisfied. As a result, similarly to Embodiment 1, a difference between the optical crosstalk from the high sensitivity pixel 601 to the low sensitivity pixel 602 and the optical crosstalk from the low sensitivity pixel 602 to the high sensitivity pixel 601 can be reduced.

Further, as indicated in FIGS. 10A and 10B, the second isolating portion 330-2 is formed such that the following Condition 2-1 is satisfied.

Condition 2-1: In the plan view, the distance L21 from the center of the low sensitivity pixel 602 to the second isolating portion 330-2 is longer than the distance L12 from the center of the low sensitivity pixel 602 to the first isolating portion 330-1.

By satisfying the Condition 2-1, a decrease in the distance between the semiconductor region constituting the second isolating portion 330-2 to which the anode potential is supplied and the first semiconductor region 301 to which the cathode potential is supplied can be suppressed, and the generation of (increase in) noise can be suppressed.

Further, in Embodiment 3, the following Condition 2-2 is also satisfied, as indicated in FIGS. 10A and 10B.

Condition 2-2: In the plan view, the distance L22 from the center of the high sensitivity pixel 601 to the second isolating portion 330-2 is approximately the same as the distance L21 from the center of the low sensitivity pixel 602 to the second isolating portion 330-2.

By satisfying the Condition 2-2, dispersion of the influence of the electric field between the anode and the cathode on the pixels can be reduced. Specifically, the difference between the influence of the electric field between the anode and the cathode on the high sensitivity pixel 601 and the influence of the electric field between the anode and the cathode on the low sensitivity pixel 602 can be reduced.

The Condition 2-2 may be interpreted as the following Condition 2-3.

Condition 2-3: In the plan view, the distance from the cathode electrode (contact plug 326) to the anode electrode (contact plug 324) of the high sensitivity pixel 601, and the distance from the cathode electrode to the anode electrode of the low sensitivity pixel 602, are approximately the same.

### Embodiment 4

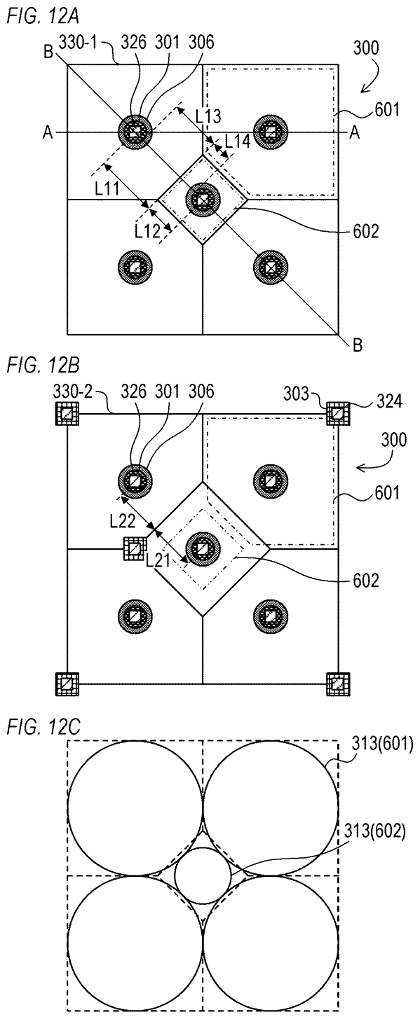

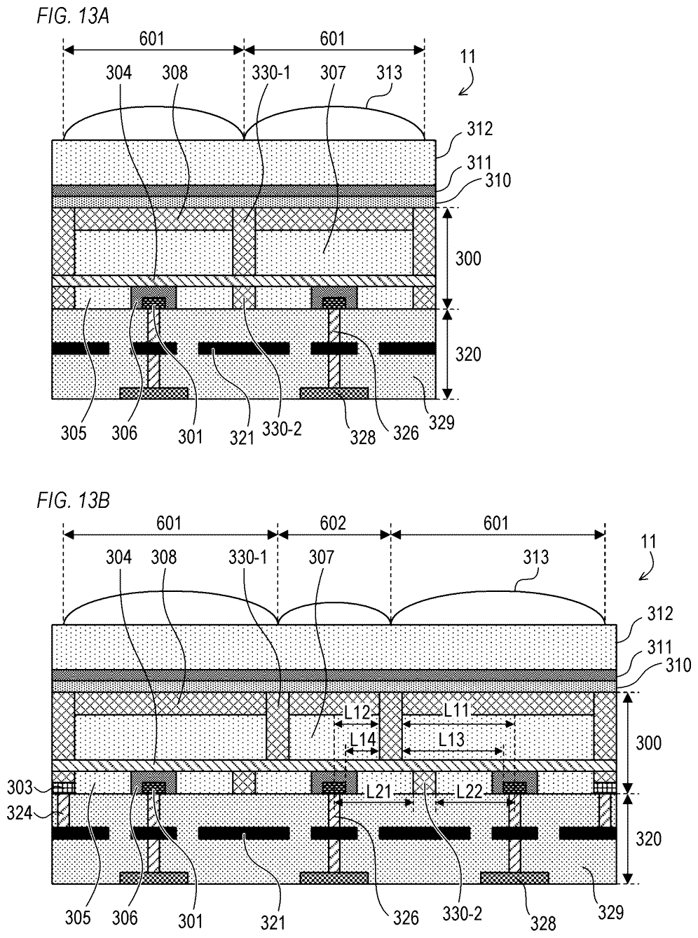

FIGS. 12A to 12C, 13A and 13B indicate a structure of the sensor substrate 11 of a photoelectric conversion device according to Embodiment 4. FIGS. 12A to 12C are plan views depicting a configuration of the pixel region 12. FIGS. 12A and 12B are schematic diagrams viewing the semiconductor layer 300 of the sensor substrate 11 from the first surface side, and FIG. 12C is a schematic diagram indicating an arrangement of the micro-lenses 313. FIG. 12A indicates an arrangement of the first isolating portion 330-1, the contact plug 326 of the cathode, and the like, and FIG. 12B indicates an arrangement of the second isolating portion 330-2, the contact plug 324 of the anode, the contact plug 326 of the cathode, and the like. FIG. 13A is a cross-sectional view sectioned at the A-A line in FIG. 12A, and FIG. 13B is a cross-sectional view sectioned at the B-B line in FIG. 12A. In the following, a configuration that is different from Embodiment 3 will be described.

In Embodiment 3, one low sensitivity pixel 602 is disposed for three high sensitivity pixels 601. Specifically, four pixels (three high sensitivity pixels 601 and one low sensitivity pixel 602), are arranged in two rows×two columns, as indicated in FIGS. 10A to 10C.

In Embodiment 4, one low sensitivity pixel 602 is disposed for four high sensitivity pixels 601. Specifically, one low sensitivity pixel 602 is disposed at the center of four high sensitivity pixels 601 arranged in two rows×two columns, as indicated in FIGS. 12A to 12C. Thereby a Bayer array of the high sensitivity pixels 601 can be implemented.

Further, in Embodiment 4, both the Conditions 1-1 and 1-2 in Embodiment 1 and the Conditions 2-1 and 2-2 in Embodiment 3 are satisfied. Therefore both the effects similar to Embodiment 1 and the effects similar to Embodiment 3 can be implemented.

### Embodiment 5

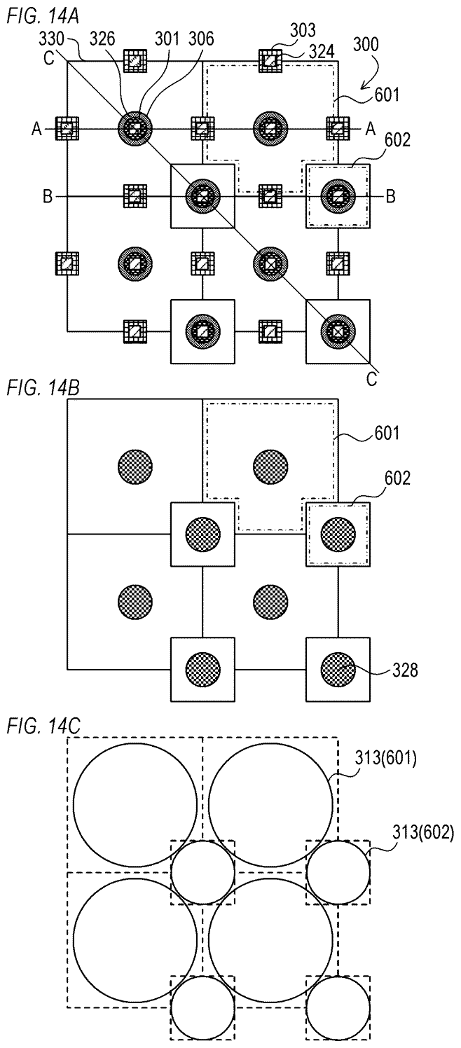

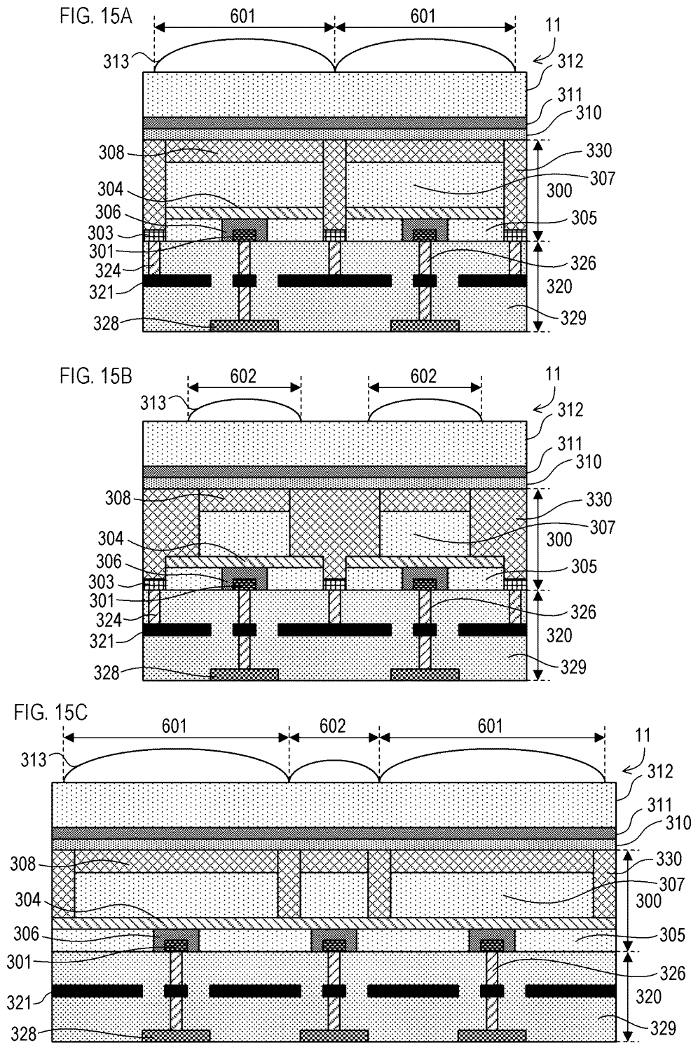

FIGS. 14A to 14C and 15A to 15C indicate a structure of the sensor substrate 11 of a photoelectric conversion device according to Embodiment 5. FIGS. 14A to 14C are plan views depicting a configuration of the pixel region 12. FIG. 14A is a schematic diagram viewing the semiconductor layer 300 of the sensor substrate 11 from the first surface side, FIG. 14B is a schematic diagram indicating an arrangement of the bonding portions 328 (metal bondings), and FIG. 14C is a schematic diagram indicating an arrangement of the micro-lenses 313. FIG. 15A is a cross-sectional view sectioned at the A-A line in FIG. 14A, FIG. 15B is a cross-sectional view sectioned at the B-B line in FIG. 14A, and FIG. 15C is a cross-sectional view sectioned at the C-C line in FIG. 14A. In the following, a configuration that is different from Embodiment 1 will be described.

In Embodiment 1, the size of the low sensitivity pixel 602 is smaller than the size of the high sensitivity pixel 601 (the size of the high sensitivity pixel 601 is larger than the size of the low sensitivity pixel 602). In such a configuration, however, an arrangement of the cathode electrodes (contact plugs 326) and an arrangement of the metal bondings (bonding portions 328) influence improving the degree of integration of the pixels and further miniaturization of the pixels.

Therefore in Embodiment 5, the arrangement of the cathode electrodes (contact plugs 326) and the arrangement of the metal bondings (bonding portions 328) are optimized, so that the degree of integration of the pixels can improve, and pixels can be further miniaturized. In Embodiment 5, a plurality of high sensitivity pixels 601 are disposed at approximately equal intervals in the row direction (a first direction) and in the column direction (a second direction, which is vertical to the first direction) respectively, as indicated in FIGS. 14A to 14C. In the same manner, a plurality of low sensitivity pixels 602 are disposed at approximately equal intervals in the row direction and in the column direction respectively. Then a plurality of cathode electrodes (contact plugs 326) which correspond to the plurality of pixels respectively, including the plurality of high sensitivity pixels 601 and the plurality of low sensitivity pixels 602, are disposed at approximately equal intervals in a first diagonal direction and in a second diagonal direction respectively. The first diagonal direction is a direction of equally dividing the row direction and the column direction into two (a third direction, which equally divides the first direction and the second direction into two), and the second diagonal direction is a direction which is vertical to the first diagonal direction (a fourth direction, which is vertical to the third direction). Furthermore, the positions of the plurality of bonding portions 328 (metal bondings), which correspond to the plurality of pixels respectively, are positions which are approximately the same as the positions of the plurality of cathode electrodes (contact plugs 326), as indicated in FIG. 14B.

Thereby a configuration where the low sensitivity pixels 602 are ½ pitch shifted from the high sensitivity pixels 601 respectively (a configuration where one low sensitivity pixel 602 is disposed approximately at the center of four high sensitivity pixels 601 arrayed in two rows×two columns) can be easily used. Further, it is easier to improve the degree of integration of the pixels and to further miniaturize the pixels.

Further, in Embodiment 5, the distance between the cathode electrode (contact plug 326) and the anode electrode (contact plug 324) is approximately constant, as indicated in FIG. 14A. Furthermore, in each of the row direction and the column direction, the cathode electrodes (contact plugs 326) and the anode electrodes (contact plugs 324) are disposed at approximately equal intervals. In each of the first diagonal direction and the second diagonal direction as well, the cathode electrodes (contact plugs 326) and the anode electrodes (contacts plugs 324) are disposed at approximately equal intervals. By this arrangement as well, it becomes possible to improve the degree of integration, and to further miniaturize the pixels.

In FIG. 14A, the anode electrodes (contact plugs 324) are disposed on all four sides of the high sensitivity pixel 601, but the anode electrodes may be thinned out. For example, one electrode may be disposed for a plurality of pixels.

Further, in Embodiment 5, there is an area where the isolating portion 330 does not exist on the first surface side of the sensitivity region (the seventh semiconductor region 307), as indicated in FIG. 15C. Since the isolating portion 330 (the second semiconductor region 302) is not exposed to the first surface, this prevents electric charges (noise), generated near the first surface, from entering the sensitivity region through the second conductivity type semiconductor region.

### Embodiment 6

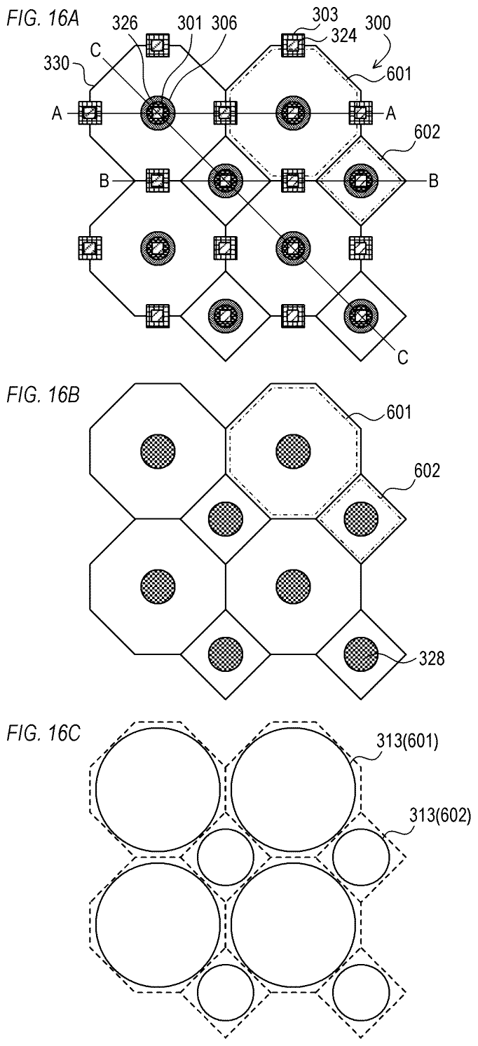

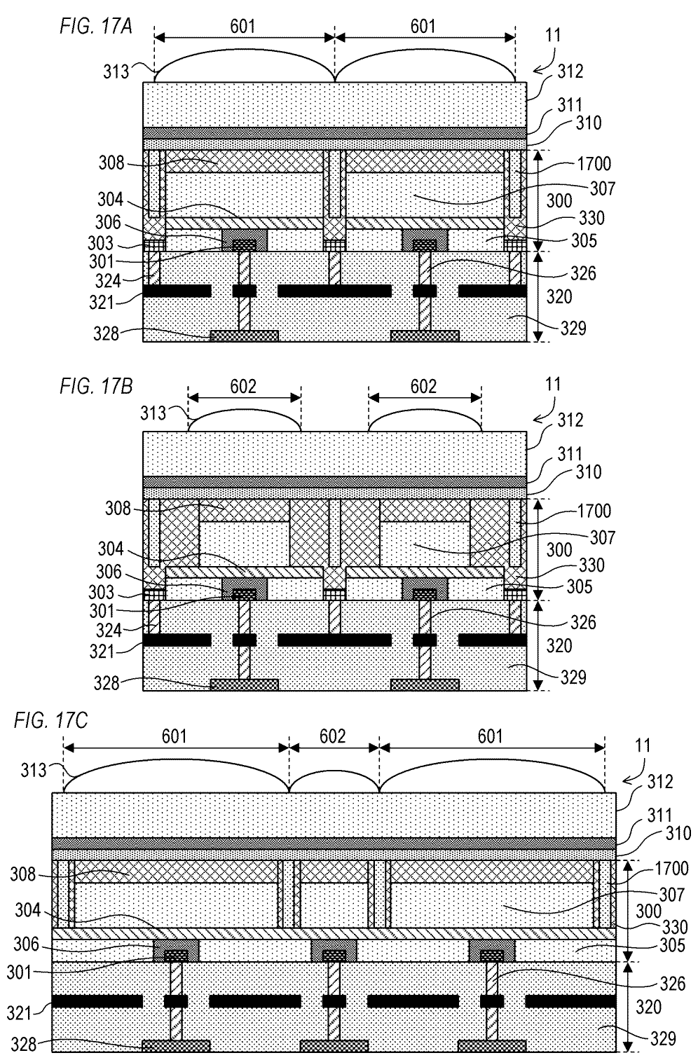

FIGS. 16A to 16C and 17A to 17C indicate a structure of the sensor substrate 11 of a photoelectric conversion device according to Embodiment 6. FIGS. 16A to 16C are plan views depicting a configuration of the pixel region 12. FIG. 16A is a schematic diagram viewing the semiconductor layer 300 of the sensor substrate 11 from the first surface side, FIG. 16B is a schematic diagram indicating an arrangement of bonding portions 328 (metal bondings), and FIG. 16C is a schematic diagram indicating an arrangement of the micro-lenses 313. FIG. 17A is a cross-sectional view sectioned at the A-A line in FIG. 16A, FIG. 17B is a cross-sectional view sectioned at the B-B line in FIG. 16A, and FIG. 17C is a cross-sectional view sectioned at the C-C line in FIG. 16A. In the following, a configuration that is different from Embodiment 5 will be described.

In Embodiment 6, just like Embodiment 5, one low sensitivity pixel 602 is disposed approximately at the center of four high sensitivity pixels 601, arranged in 2 rows×two columns, as indicated in FIGS. 16A to 16C.

Further, in Embodiment 6, the isolating portion 330 surrounds the high sensitivity pixel 601 in an approximately octagonal shape, and surrounds the low sensitivity pixel 602 in an approximately square shape, formed by approximately four octagonal shapes which correspond to the four high sensitivity pixels 601 respectively, as indicated in FIGS. 16A to 16C.

Further, in Embodiment 6, a trench 1700, which does not penetrate the isolation portion 330 in the depth direction, is formed in the isolating portion 330, as indicated in FIGS. 17A to 17C. By forming the trench 1700, the optical crosstalk can be further reduced.

Since the isolating portion 330 surrounds the high sensitivity pixel 601 in an approximately octagonal shape, right angle portions can be minimized in the isolating portion 330. Minimizing right angle portions can suppress electric field concentration. Further, the trench can be formed more easily thereby, and damage caused to the semiconductor region when the trench is formed can be reduced, and the generation of (increase in) noise due to this damage can be prevented.

In Embodiment 5, a part of the micro-lenses 313 of the high sensitivity pixels 601 overlap with the region of the low sensitivity pixels 602, as indicated in FIG. 14C, hence unnecessary light enters the low sensitivity pixels 602. In Embodiment 6, on the other hand, the isolating portion 330 surrounds the high sensitivity pixel 601 in an octagonal shape, whereby overlapping of micro-lens 313 of another pixel on a pixel region can be prevented, as indicated in FIG. 16C. Therefore, entry of unnecessary light into pixels can be prevented.

### Embodiment 7

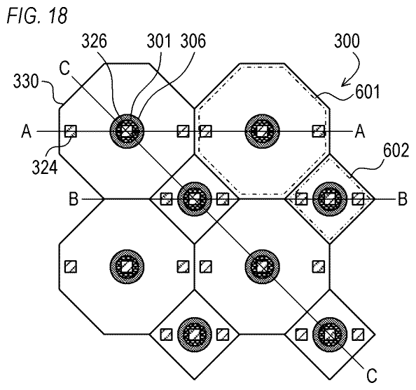

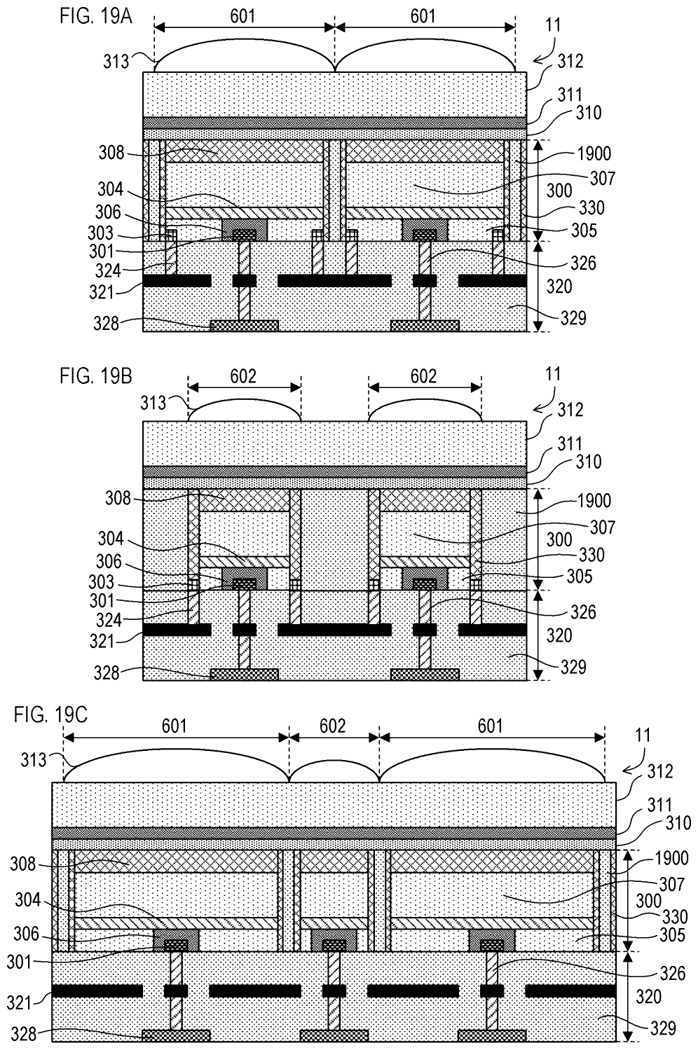

FIGS. 18 and 19A to 19C indicate a structure of the sensor substrate 11 of a photoelectric conversion device according to Embodiment 7. FIG. 18 is a plan view depicting a configuration of the pixel region 12, and is a schematic diagram viewing the semiconductor layer 300 of the sensor substrate 11 from the first surface side. FIG. 19A is a cross-sectional view sectioned at the A-A line in FIG. 18, FIG. 19B is a cross-sectional view sectioned at the B-B line in FIG. 18, and FIG. 19C is a cross-sectional view sectioned at the C-C line in FIG. 18. In the following, a configuration that is different from Embodiment 6 will be described.

In Embodiment 6, the trench 1700, which does not penetrate the isolating portion 330 in the depth direction, is formed in the isolating portion 330, as indicated in FIGS. 17A to 17C. In Embodiment 7, a trench 1900, which penetrates the isolating portion 330 in the depth direction, is formed in the isolating portion 330, as indicated in FIGS. 19A to 19C. By forming the trench which penetrates, emission crosstalk can be reduced compared with the case of the trench which does not penetrate.

In the case of forming the trench which penetrates, the anode electrode (contact plug 324) must be independently disposed for each of the two pixels sandwiching the trench respectively. This is why a number of contact plugs 324 (and the third semiconductor regions 303) and the arrangement thereof are different between Embodiment 6 (FIGS. 16A and 17A to 17C) and Embodiment 7 (FIGS. 18 and 19A to 19C).

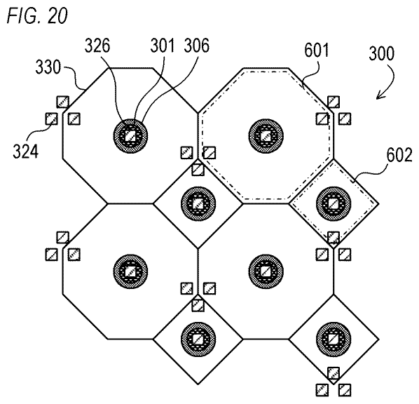

The arrangement of the anode electrodes (contact plugs 324) is not especially limited, and a plurality of anode electrodes (contact plugs 324) may be concentrated at one location, as indicated in FIG. 20, for example. Thereby the degree of integration of the pixels can be further improved, or the pixels can be further miniaturized. If the configuration in FIG. 20, where the isolating portion 330 surrounds the high sensitivity pixel 601 in an approximately octagonal shape and surrounds the low sensitivity pixel 602 in an approximately square shape, is used, a plurality of anode electrodes (contact plugs 324) can be easily concentrated at one location.

### Embodiment 8

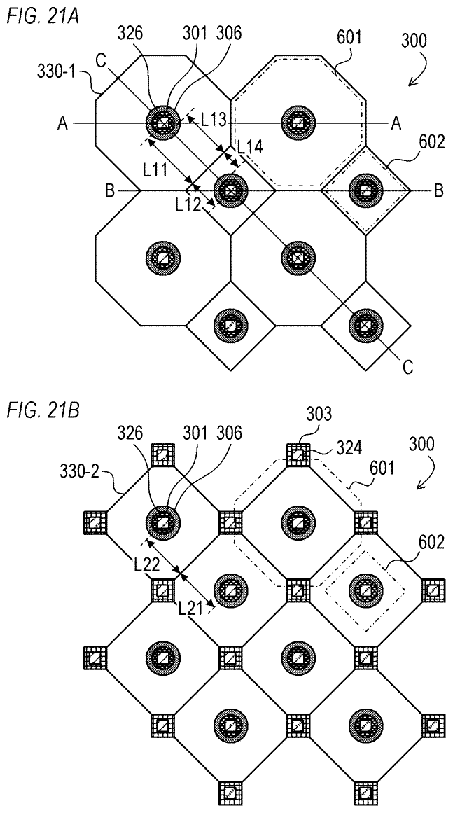

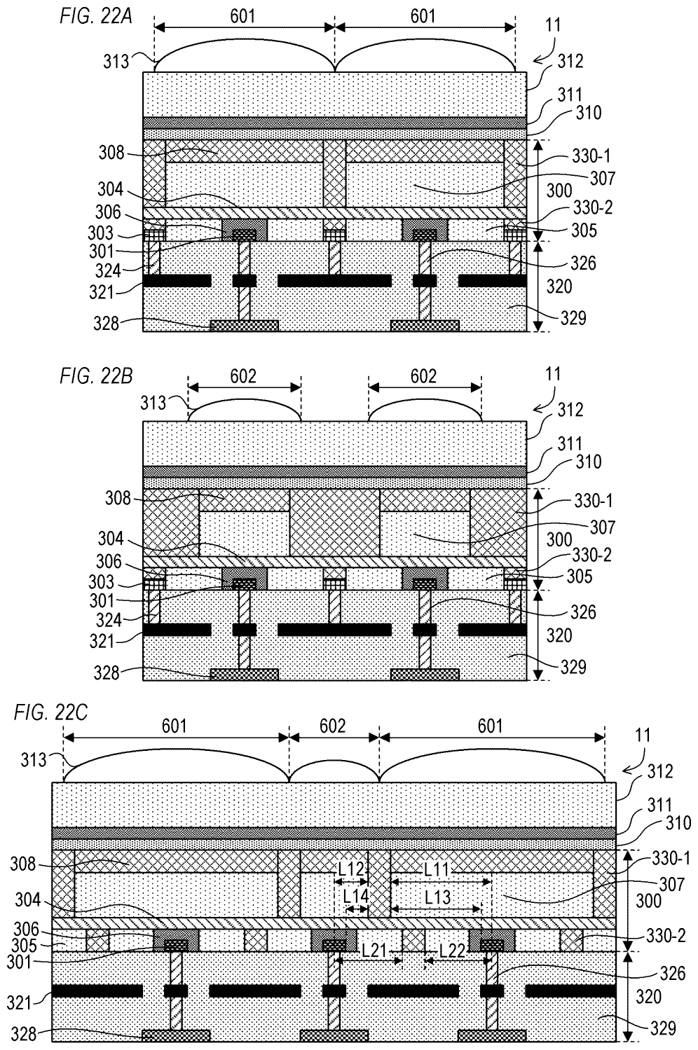

FIGS. 21A, 21B and 22A to 22C indicate a structure of the sensor substrate 11 of a photoelectric conversion device according to Embodiment 8. FIGS. 21A and 21B are plan views depicting a configuration of the pixel region 12, and are schematic diagrams viewing the semiconductor layer 300 of the sensor substrate 11 from the first surface side. FIG. 22A is a cross-sectional view sectioned at the A-A line in FIG. 21A, FIG. 22B is a cross-sectional view sectioned at the B-B line in FIG. 21A, and FIG. 22C is a cross-sectional view sectioned at the C-C line in FIG. 21A. In the following, a configuration that is different from Embodiment 6 will be described.

In Embodiment 8, the first isolating portion 330-1 and the second isolating portion 330-2 are disposed as the isolating portions to isolate the plurality of pixels, as indicated in FIGS. 21A, 21B, and 22A to 22C, just like Embodiment 3 and Embodiment 4. FIG. 21A indicates an arrangement of the first isolating portion 330-1, the contact plug 326 of the cathode, and the like, and FIG. 21B indicates an arrangement of the second isolating portion 330-2, the contact plug 324 of the anode, the contact plug 326 of the cathode, and the like.

Further, in Embodiment 8, both the Conditions 1-1 and 1-2 in Embodiment 1 and the Conditions 2-1 and 2-2 in Embodiment 3 are satisfied. The other configuration is the same as Embodiment 6. As indicated in FIG. 21B, a plurality of second isolating portions 330-2 are disposed at approximately equal intervals in the first diagonal direction and the second diagonal direction respectively. Thereby the Conditions 2-1 and 2-2 are satisfied more easily.

As described above, in Embodiment 8, the effects similar to Embodiment 1, the effects similar to Embodiment 3, the effects similar to Embodiment 4, and the effects similar to Embodiment 6 can be implemented.

### Embodiment 9

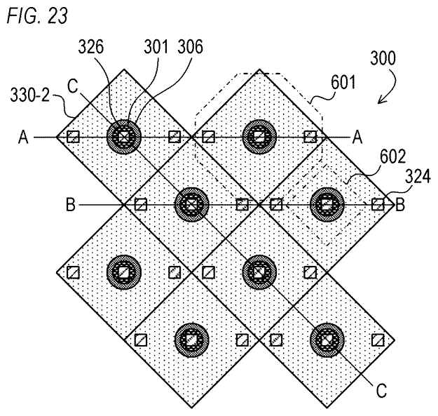

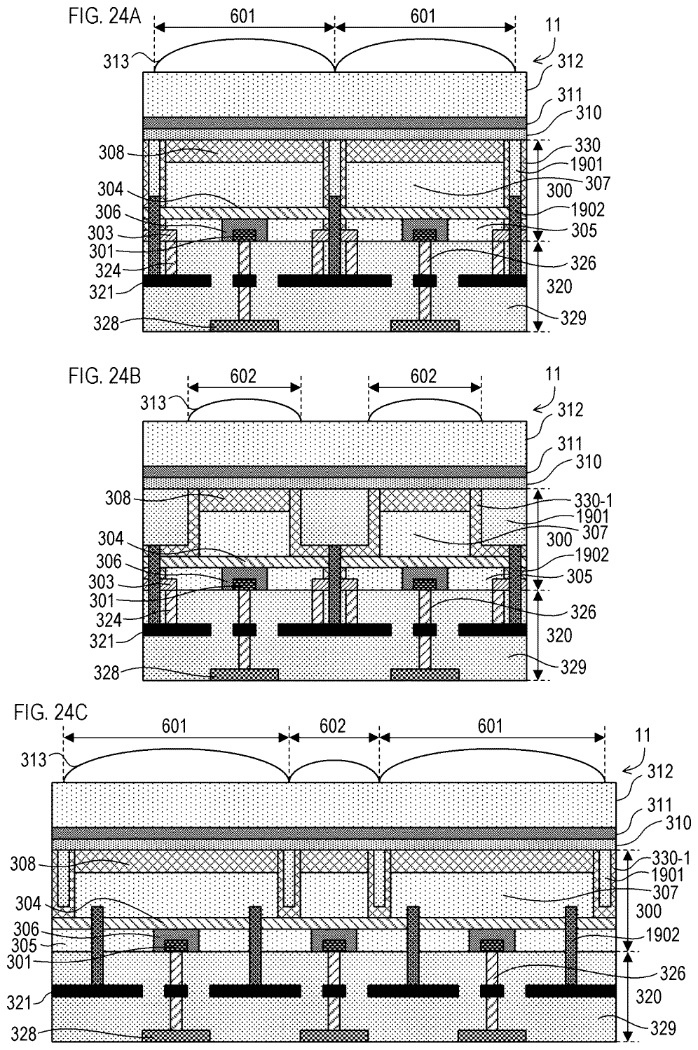

FIGS. 23 and 24A to 24C indicate a structure of a sensor substrate 11 of a photoelectric conversion device according to Embodiment 9. FIG. 23 is a plan view depicting a configuration of the pixel region 12, and is a schematic diagram viewing the semiconductor layer 300 of the sensor substrate 11 from the first surface side. FIG. 23 indicates an arrangement of the second isolating portion 330-2, the contact plug 324 of the anode, the contact plug 326 of the cathode, and the like. FIG. 24A is a cross-sectional view sectioned at the A-A line in FIG. 23, FIG. 24B is a cross-sectional view sectioned at the B-B line in FIG. 23, and FIG. 24C is a cross-sectional view sectioned at the C-C line in FIG. 23. In the following, configuration that is different from Embodiment 8 will be described.

In Embodiment 9, a trench 1901, which does not penetrate the first isolating portion 330-1 in the depth direction, is formed in the first isolating portion 330-1, as indicated in FIGS. 24A to 24C. Further, a trench 1902, which does not penetrate the second isolating portion 330-2, is formed in the second isolating portion 330-2. In Embodiment 8, the second isolating portion 330-2 is formed on the first surface side of the fourth semiconductor region 304, but the trench 1902 of Embodiment 9 is also formed on the second surface side of the fourth semiconductor region 304. By forming the trenches 1901 and 1902, the optical crosstalk can be further reduced. The trenches 1901 and 1902 may both have a deep trench isolation (DTI) structure. The trenches 1901 and 1902 may be constituted of an insulating film, a fixed charge film, a metal member, polysilicon, or a combination of a plurality of these members. For example, an insulating film may be buried in the trench 1901, and a metal may be buried in the trench 1902. A same material may be buried in the trench 1901 and the trench 1902.

Another characteristic of Embodiment 9 is that, as indicated in FIG. 23, the arrangement of the cathode electrodes (contact plugs 326) and the anode electrodes (contact plugs 324) is the same between the high sensitivity pixel 601 and the low sensitivity pixel 602.

### Embodiment 10

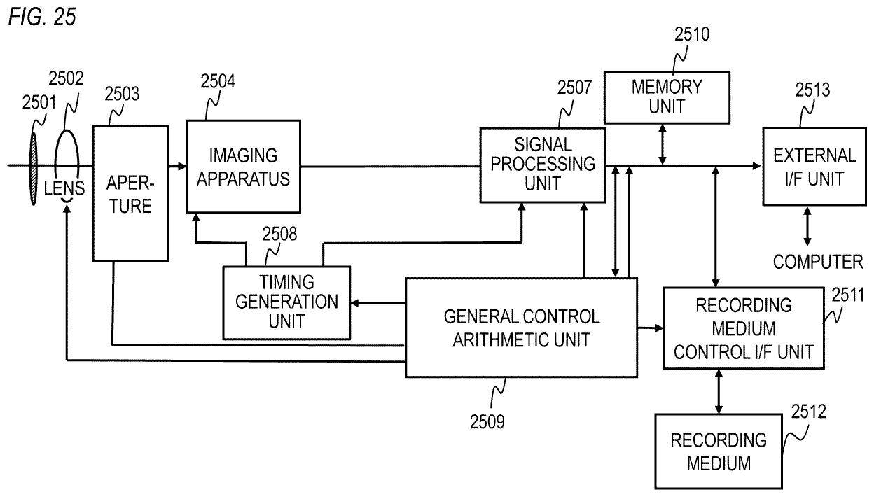

A photoelectric conversion system according to Embodiment 10 will be described with reference to FIG. 25. FIG. 25 is a block diagram depicting a general configuration of the photoelectric conversion system according to Embodiment 10.

The photoelectric conversion devices described in Embodiments 1 to 9 are applicable to various photoelectric conversion systems. A photoelectric conversion system includes at least the photoelectric conversion device according to any of the above embodiments, and a signal processing unit which processes signals outputted from the photoelectric conversion device. Examples of an apparatus to which this photoelectric conversion system is applicable are: a digital still camera, a digital camcorder, a security camera, a copier, a facsimile, a portable telephone, an on-vehicle camera, an observation satellite, a sensor, and a measuring instrument. A camera module constituted of an optical system (e.g. lens) and an imaging apparatus is also included in the apparatus to which the photoelectric conversion system is applied. FIG. 25 is a block diagram of a digital still camera, which is an example of these applications.

The photoelectric conversion system exemplified in FIG. 25 includes an imaging apparatus 2504, which is an example of the photoelectric conversion device, and a lens 2502, which forms an optical image of a subject on the imaging apparatus 2504. The photoelectric conversion system also includes an aperture 2503 which varies the quantity of light that passes through the lens 2502, and a barrier 2501 for protecting the lens 2502. The lens 2502 and the aperture 2503 constitute an optical system to collect light to the imaging apparatus 2504. The imaging apparatus 2504 is a photoelectric conversion device (imaging apparatus) according to any one of the embodiments described above, and converts the optical image, formed by the lens 2502, into electric signals.

The photoelectric conversion system also includes a signal processing unit 2507, which is a signal generation unit that generates an image by processing an output signal outputted from the imaging apparatus 2504. The signal processing unit 2507 performs operations to output image data after performing various corrections and compressions as required. The signal processing unit 2507 may be formed on the semiconductor substrate on which the imaging apparatus 2504 is disposed, or may be formed on a semiconductor substrate that is separate from the imaging apparatus 2504. The imaging apparatus 2504 and the signal processing unit 2507 may be formed on the same semiconductor substrate.

The photoelectric conversion system further includes a memory unit 2510 which temporarily stores image data, and an external interface unit (external I/F unit) 2513 to communicate with an external computer, or the like. Furthermore, the photoelectric conversion system includes a recording medium 2512 (e.g. semiconductor memory) to record or read imaged data, and a recording medium control interface unit (recording medium control I/F unit) 2511 to record or read from the recording medium 2512. The recording medium 2512 may be built-in the photoelectric conversion system, or removeable therefrom.

Further, the photoelectric conversion system includes a general control arithmetic unit 2509, which performs various arithmetic operations and controls the digital still camera in general, and a timing generation unit 2508, which outputs various timing signals to the imaging apparatus 2504 and the signal processing unit 2507. Here the timing signals and the like may be inputted externally, and it is sufficient if the photoelectric conversion system includes at least the imaging apparatus 2504 and the signal processing unit 2507, which processes output signals outputted from the imaging apparatus 2504.

The imaging apparatus 2504 outputs an imaging signal to the signal processing unit 2507. The signal processing unit 2507 performs predetermined signal processing for the imaging signal outputted from the imaging apparatus 2504, and outputs image data. The signal processing unit 2507 generates an image using the imaging signal.

Thus according to Embodiment 10, a photoelectric conversion system, to which the photoelectric conversion device (imaging apparatus) according to any one of the above embodiments is applied, can be implemented.

### Embodiment 11

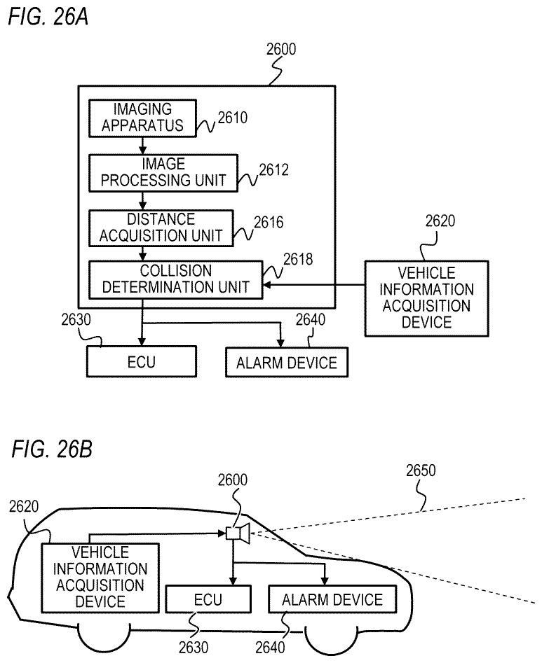

A photoelectric conversion system and a mobile body according to Embodiment 11 will be described with reference to FIGS. 26A and 26B. FIG. 26A is a diagram depicting a configuration of the photoelectric conversion system according to Embodiment 11, and FIG. 26B is a diagram depicting a configuration of the mobile body according to Embodiment 11.

FIG. 26A is an example of the photoelectric conversion system related to an on-vehicle camera. The photoelectric conversion system 2600 includes an imaging apparatus 2610. The imaging apparatus 2610 is the photoelectric conversion device (imaging apparatus) according to any one of the above embodiments. The photoelectric conversion system 2600 includes an image processing unit 2612, which performs image processing on a plurality of image data acquired by the imaging apparatus 2610. The photoelectric conversion system 2600 also includes a distance acquisition unit 2616 which calculates the distance to a subject, and a collision determination unit 2618 which determines if collision is possible based on the calculated distance. Here the distance acquisition unit 2616 may acquire the distance information to a time of flight (ToF) subject, or may acquire the distance information using parallax information or the like. In other words, the distance information is information on parallax, defocus amount, distance to the subject, or the like. The collision determination unit 2618 may determine the collision possibility using any of this distance information. The distance information acquisition means may be implemented by dedicated hardware, or may be implemented by a software module. Further, the distance information acquisition means may be implemented by a field programmable gate array (FPGA), an application specific integrated circuit (ASIC), or the like, or may be implemented by a combination thereof.

The photoelectric conversion system 2600 is connected to a vehicle information acquisition device 2620, and can acquire such vehicle information as vehicle speed, yaw rate and steering angle. Further, an ECU 2630, which is a control device that outputs a control signal to generate a braking force on the vehicle based on the determination result by the collision determination unit 2618, is connected to the photoelectric conversion system 2600. The photoelectric conversion system 2600 is also connected to an alarm device 2640, which emits an alarm to alert the driver of the vehicle based on the determination result by the collision determination unit 2618. For example, in a case where collision probability is high according to the determination result by the collision determination unit 2618, the ECU 2630 controls the vehicle to prevent collision or to minimize damage by applying the brakes, letting up on the accelerator, reducing engine output, and the like. The alarm device 2640 alerts the user by outputting an alarm (e.g. sound), displaying the alarm information on a screen of a car navigation system or the like, or by applying vibration to a seat belt or steering wheel, for example.

In Embodiment 11, the photoelectric conversion system 2600 captures images around the vehicle, such as the forward or backward areas of the vehicle. FIG. 26B indicates the photoelectric conversion system in the case of capturing an image of the forward area of the vehicle (imaging range 2650). The vehicle information acquisition device 2620 sends an instruction to the photoelectric conversion system 2600 or the imaging apparatus 2610. By this configuration, the accuracy of distance measurement can be improved.

Here an example of controlling a vehicle to avoid collision with another vehicle was described, but the present invention is also applicable to control of a vehicle so as to automatically drive following another vehicle, or control of a vehicle so as to automatically drive without deviating from a lane, for example. Further, application of the photoelectric conversion system is not limited to such a vehicle as a car, but is applicable also to a ship, an airplane, or such a mobile body (moving device) as an industrial robot. The mobile body here includes one or both of a drive force generation unit which generates a drive force used mainly for moving the mobile body, and a rotating member which is used to move the mobile body. The drive force generation unit may be an engine, a motor, or the like. The rotating member may be a tire, wheel, the screws of a ship, propeller of an airplane, or the like. Application of the present invention is not limited to a mobile body, but is applicable to a wide range of apparatuses that use object recognition, such as an intelligent transportation system (ITS).

### Embodiment 12

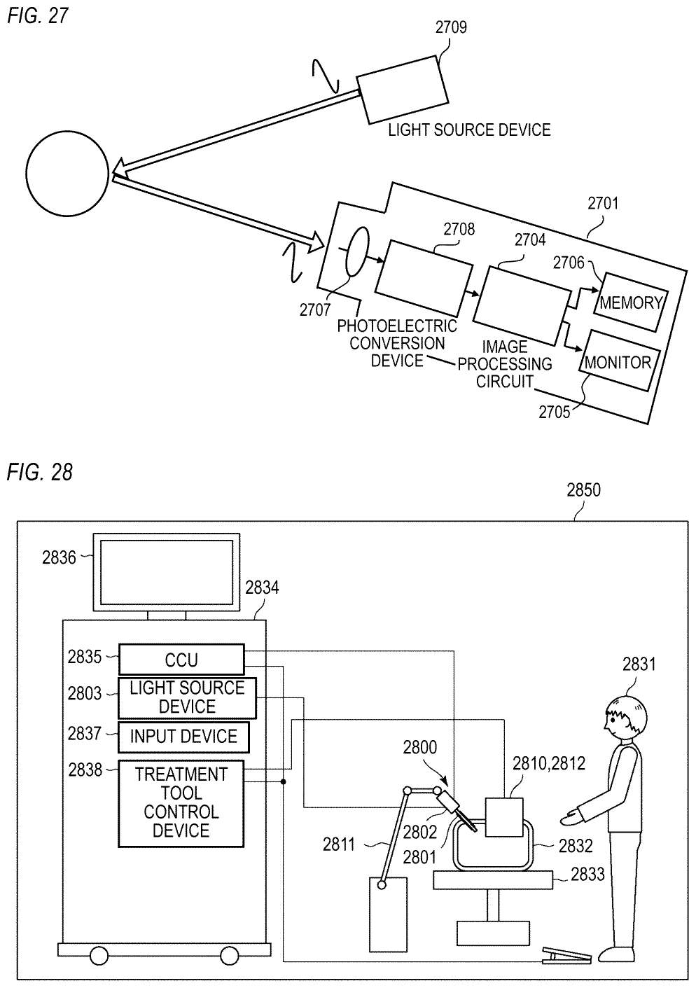

A photoelectric conversion system according to Embodiment 12 will be described with reference to FIG. 27. FIG. 27 is a block diagram depicting a configuration example of a distance image sensor, which is the photoelectric conversion system according to Embodiment 12.

As indicated in FIG. 27, the distance image sensor 2701 includes an optical system 2707, a photoelectric conversion device 2708, an image processing circuit 2704, a monitor 2705, and a memory 2706. The distance image sensor 2701 receives light, which is emitted from a light source device 2709 to a subject and is reflected by the surface of the subject, whereby a distance image in accordance with the distance to the subject can be acquired.

The optical system 2707 is constituted of one or a plurality of lenses, and guides an image light (incident light) from the subject to the photoelectric conversion device 2708, and forms an image thereof on a light-receiving surface (sensor unit) of the photoelectric conversion device 2708.

For the photoelectric conversion device 2708, the photoelectric conversion device according to any of the above embodiments is used, and a distance signal, which indicates a distance determined based on a light-receiving signal outputted from the photoelectric conversion device 2708, is supplied to the image processing circuit 2704.

The image processing circuit 2704 performs image processing to construct a distance image based on the distance signal supplied from the photoelectric conversion device 2708. The distance image (image data) acquired by this image processing is supplied to the monitor 2705 and is displayed there, or is supplied to the memory 2706 and is stored (recorded) there.

In the distance image sensor 2701 configured like this, a more accurate distance image can be acquired, for example, due to the improvement in the characteristics of the pixels, by applying the above mentioned photoelectric conversion device.

### Embodiment 13

A photoelectric conversion system according to Embodiment 13 will be described with reference to FIG. 28. FIG. 28 is a diagram depicting an example of a general configuration of an endoscopic surgery system, which is the photoelectric conversion system according to Embodiment 13.

FIG. 28 indicates a state where an operator (physician) 2831 is performing surgery on a patient 2832 on a patient bed 2833 using the endoscopic surgery system 2850. As illustrated here, the endoscopic surgery system 2850 is constituted of an endoscope 2800, a surgical tool 2810, and a cart 2834 on which various devices for the endoscopic surgery are equipped.

The endoscope 2800 is constituted of a lens tube 2801 of which a predetermined length of the region from the tip is inserted into a body cavity of the patient 2832, and a camera head 2802 which is connected to a base end of the lens tube 2801. In the illustrated example, the endoscope 2800 is constituted of a hard mirror which includes a hard lens tube 2801, but the endoscope 2800 may be constituted of a soft mirror which includes a soft lens tube.

An opening portion, in which an objective lens is fitted, is disposed at the tip of the lens tube 2801. A light source device 2803 is connected to the endoscope 2800, so that light generated by the light source device 2803 is guided to the tip of the lens tube via a light guide extending inside the lens tube 2801, and is emitted to the observation target inside the body cavity of the patient 2832 via the objective lens. The endoscope 2800 may be a direct viewing scope or an oblique or side viewing scope.

An optical system and a photoelectric conversion device are disposed inside the camera head 2802, and reflected light (observation light) from the observation target is collected to the photoelectric conversion device by this optical system. The observation light is photo-electrically converted by the photoelectric conversion device, whereby an electric signal corresponding to the observation light, that is, an image signal corresponding to the observation image, is generated. For this photoelectric conversion device, the photoelectric conversion device (imaging apparatus), according to any of the above embodiments, can be used. This image signal is sent to a camera control unit (CCU) 2835 as RAW data.

The CCU 2835 is constituted of a central processing unit (CPU), a graphics processing unit (GPU), and the like, and comprehensively controls operations of the endoscope 2800 and the display device 2836. Further, the CCU 2835 receives an image signal from the camera head 2802, and performs various types of image processing, such as development processing (demosaic processing), on the image signal to display an image based on the image signal.

By the control from the CCU 2835, the display device 2836 displays an image based on the image signal on which image processing was performed by the CCU 2835.

The light source device 2803 is constituted of a light source, such as a light-emitting diode (LED), for example, and supplies an illumination light to the endoscope 2800 to image the surgical region, or the like.

An input device 2837 is an input interface to the endoscopic surgery system 2850. The user can input various types of information and instructions to the endoscopic surgery system 2850 via the input device 2837.

A treatment tool control device 2838 controls the driving of an energy treatment tool 2812 for cauterizing or incising a tissue, sealing a blood vessel, or the like.

The light source device 2803, which supplies illumination light to image a surgical region to the endoscope 2800, can be a white light source constituted of an LED, a laser light source, or a combination thereof, for example. In the case of the white light source constituted of a combination of RGB laser light sources, the output intensity and output timing of each color (each wavelength) can be controlled at high precision, hence the white balance of a captured image can be adjusted in the light source device 2803. Further, in this case, by emitting laser beams from each of the R, G and B laser light sources respectively to the observation target in time division, and by controlling the driving of the imaging elements of the camera head 2802 synchronizing with the emitting timing, an image corresponding to each R, G and B can be captured in time division. According to this method, a color image can be acquired without disposing color filters in the imaging elements.

The driving of the light source device 2803 may be controlled such that the intensity of the light to be outputted changes at every predetermined time. If the driving of the imaging elements of the camera head 2802 is controlled synchronizing with the timing of changing the intensity of the light, images are acquired in time division, and these images are combined, then images in a high dynamic range without black clipping and white clipping can be generated.

The light source device 2803 may be configured such that light with a predetermined wavelength band, corresponding to special light observation, can be supplied. In the special light observation, wavelength dependency of the absorption of light in a body tissue is used. Specifically, a predetermined tissue, such as blood vessels of a mucous membrane surface layer, is imaged at high contrast by illumination light in a narrower band compared with the illumination light in normal observation (that is, white light). In the special light observation, fluorescent observation, in which an image is acquired by fluorescent light generated by emitting an excitation light, may be performed. In the fluorescent observation, an excitation light is emitted to the body tissue, and the fluorescent light generated from this body tissue is observed, or a reagent, such as indocyanine green (ICG), is locally injected into a body tissue, and an excitation light corresponding to the fluorescent wavelength of the reagent is emitted to this body tissue so as to acquire a fluorescent image, for example. The light source device 2803 may be configured such that the narrow band light and/or the excitation light corresponding to the special light observation can be supplied in this way.

### Embodiment 14

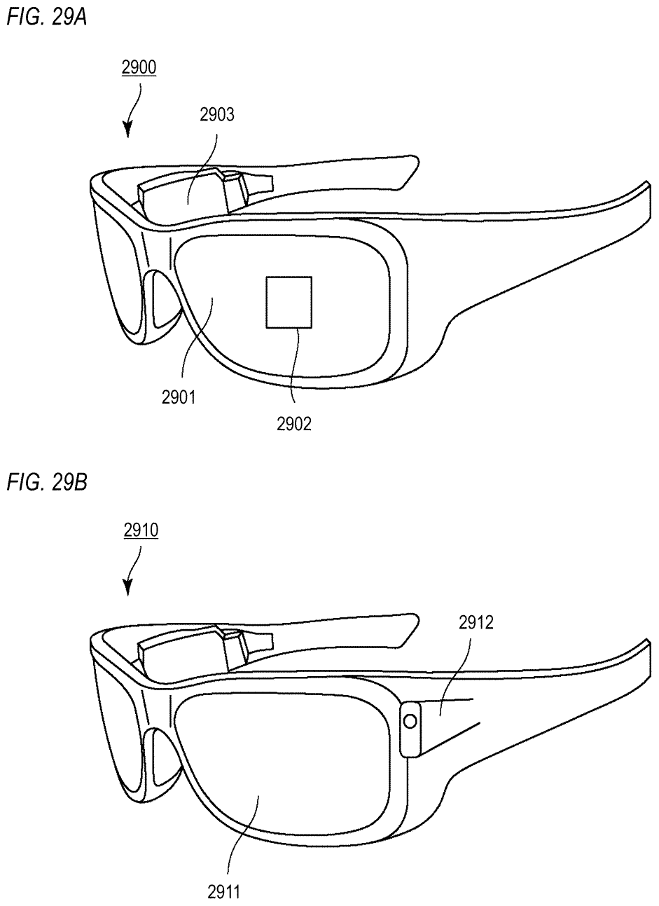

A photoelectric conversion system according to Embodiment 14 will be described with reference to FIGS. 29A and 29B. FIG. 29A indicates glasses 2900 (smart glasses), which is the photoelectric conversion system according to Embodiment 14. The glasses 2900 include a photoelectric conversion device 2902. The photoelectric conversion device 2902 is the photoelectric conversion device (imaging apparatus) according to any of the above embodiments. A display device, including such a light-emitting device as an OLED or LED, may be disposed on the rear side of the lens 2901. One photoelectric conversion device 2902 may be included, or a plurality of photoelectric conversion device 2902 may be included. A combination of a plurality of types of photoelectric conversion devices may be used. The position where the photoelectric conversion device 2902 is disposed is not limited to FIG. 29A.

The glasses 2900 further include a control device 2903. The control device 2903 functions as a power supply to supply power to the photoelectric conversion device 2902 and to the above mentioned display device. Further, the control device 2903 controls operations of the photoelectric conversion device 2902 and the display device. In a lens 2901, an optical system to collect light to the photoelectric conversion device 2902 is formed.

FIG. 29B indicates glasses 2910 (smart glasses) according to one application example. The glasses 2910 include a control device 2912, and a photoelectric conversion device corresponding to the photoelectric conversion device 2902 and a display device are equipped in the control device 2912. The photoelectric conversion device in the control device 2912 and an optical system to project light emitted from the display device are formed on a lens 2911, and an image is projected to the lens 2911.

The control device 2912 functions as a power supply to supply power to the photoelectric conversion device and the display device, and also controls operations of the photoelectric conversion device and the display device. The control device may include a line-of-sight detection unit to detect a line-of-sight of the wearer. An infrared light may be used for detecting the line-of-sight. An infrared emitting unit emits infrared light to an eyeball of the user who is gazing at the display image. By the imaging unit, including light receiving elements, detecting the reflected light of the emitted infrared light from the eyeball, a captured image of the eyeball can be acquired. A drop in image quality is reduced by including reducing means for reducing light from the infrared emitting unit to the display unit in the plan view.

The line-of-sight of the user to the display image is detected from the captured image of the eyeball acquired by image capturing using the infrared light. For line-of-sight detection using a captured image of the eyeball, a known method can be used. For example, a line-of-sight detection method based on a Purkinje image generated by reflection of the illumination light on a cornea, can be used.

Specifically, the line-of-sight detection processing based on a pupil corneal reflex method is performed. The line-of-sight of the user is detected by calculating the line-of-sight vector indicating the orientation (rotation angle) of the eyeball based on an image of the pupil included in the captured image of the eyeball and the Purkinje image, using the pupil corneal reflex method.

The display device of Embodiment 14 may include a photoelectric conversion device which has light-receiving elements, and controls the display image of the display device based on information on the line-of-sight of the user received from the photoelectric conversion device.

Specifically, based on the line-of-sight information, the display device determines a first visual field region at which the user is gazing, and a second visual field region other than the first visual field region. The first visual field region and the second visual field region may be determined by the control device of the display device, or may be determined by an external control device and received therefrom. In the display region of the display device, the display resolution of the first visual field region may be controlled to be higher than the display resolution of the second visual field region. In other words, the resolution of the second visual field region may be set to be lower than the first visual field region.

For the display region, a first display region and a second display region, which is different from the first display region, may be provided, and a region having higher priority, out of the first display region and the second display region, may be determined based on the line-of-sight information. The first display region and the second display region may be determined by the control device of the display device, or may be determined by an external control device and received therefrom. The resolution of the region having higher priority may be controlled to be higher than the resolution of a region other than the region having higher priority. In other words, the resolution of the regions of which priority is relatively low may be set to low.

AI may be used to determine the first visual field region, or the region having high priority. AI may be a model constructed using the image of the eyeball and direction in which the eyeball in the image is actually seeing as training data, so that the angle of the line-of-sight and distance to a target object to which the line-of-sight is directed are estimated from the image of the eyeball. The AI program may be included in the display device, in the photoelectric conversion device, or in an external device. In the case where an external device includes the AI program, the AI program is sent to the display device via communication.

If display is controlled based on the visual detection, the present invention can be suitably applied to smart glasses which further include a photoelectric conversion device for capturing an image of the outside. The smart glasses can display the captured external information in real-time.

### Embodiment 15

The above mentioned photoelectric conversion device and the photoelectric conversion system may be applied to such an electronic apparatus as a smartphone and a tablet.

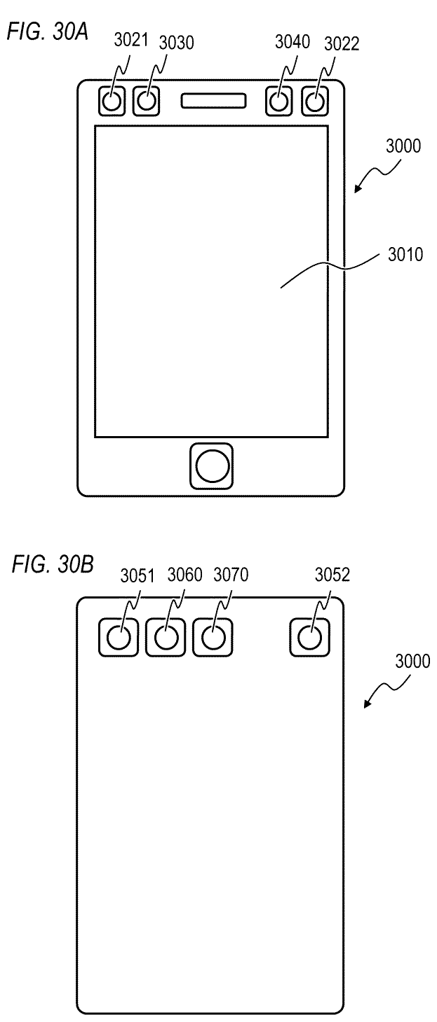

FIGS. 30A and 30B are diagrams depicting an example of an electronic apparatus 3000 equipped with the photoelectric conversion device. FIG. 30A indicates the front surface side of the electronic apparatus 3000, and FIG. 30B indicates the rear surface side of the electronic apparatus 3000.

As illustrated in FIG. 30A, a display 3010 to display images is disposed at the center of the front surface of the electronic apparatus 3000. Also along the upper side of the front surface of the electronic apparatus 3000, front cameras 3021 and 3022 for which the photoelectric conversion devices are used, an IR light source 3030 which emits infrared light, and a visible light source 3040 which emits visible light, are disposed. Further, as illustrated in FIG. 30B, along the upper side of the rear surface of the electronic apparatus 3000, rear cameras 3051 and 3052 for which the photoelectric conversion devices are used, an IR light source 3060 which emits infrared light, and a visible light source 3070 which emits visible light, are disposed.

In the electronic apparatus 3000 configured like this, higher quality images can be captured, for example, by applying the above mentioned photoelectronic conversion device. In addition to this, the photoelectric conversion device can be applied to such electronic apparatuses as an infrared sensor, a distance measurement sensor using an active infrared light source, a security camera, and a personal or biometric authentication camera. Thereby accuracy, performance, and the like of these electronic apparatuses can be improved.

### Embodiment 16

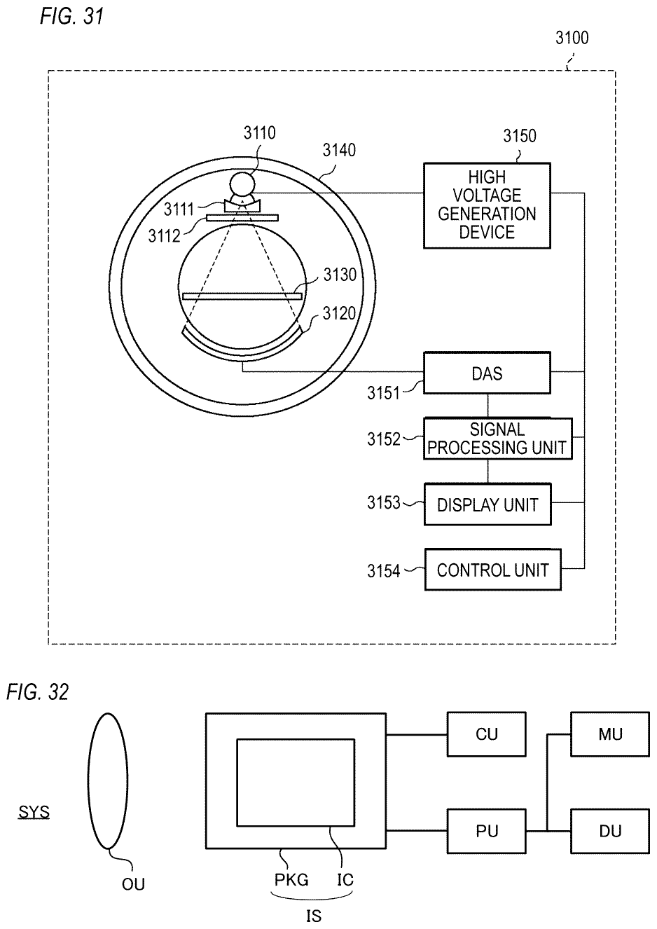

FIG. 31 is a block diagram depicting an X-ray CT device according to Embodiment 16. The above mentioned photoelectric conversion device and photoelectric conversion system are applicable to a detector of the X-ray CT device. The X-ray CT device 3100 according to Embodiment 16 includes an X-ray generation unit 3110, a wedge 3111, a collimator 3112, an X-ray detection unit 3120, a top board 3130, a rotation frame 3140, and a high voltage generation device 3150. The X-ray CT device 3100 further includes a data acquisition system (DAS) 3151, a signal processing unit 3152, a display unit 3153, and a control unit 3154.

The X-ray generation unit 3110 is constituted of a vacuum tube to generate an X-ray, for example. High voltage from the high voltage generation device 3150 and filament current are supplied to the vacuum tube of the X-ray generation unit 3110. The X-ray is generated by thermos-electrons which are emitted from a cathode (filament) to an anode (target).

The wedge 3111 is a filter to adjust the X-ray dosage emitted from the X-ray generation unit 3110. The wedge 3111 attenuates the X-ray dosage such that the X-ray emitted from the X-ray generation unit 3110 to the subject generates a predetermined distribution. The collimator 3112 is constituted of a lead plate or the like to narrow the radiation range of the X-ray transmitted through the wedge 3111. The X-ray generated in the X-ray generation unit 3110 is shaped to a cone beam shape via the collimator 3112, and is emitted to the subject on the top board 3130.

The X-ray detection unit 3120 is constituted of the above mentioned photoelectric conversion device or photoelectric conversion system. The X-ray detection unit 3120 detects an X-ray, which is emitted from the X-ray generation unit 3110 and is transmitted through the subject, and outputs the signal corresponding to the X-ray dosage to the DAS 3151.

The rotation frame 3140 is annular-shaped and is rotatable. The X-ray generation unit 3110 (wedge 3111, collimator 3112) and the X-ray detection unit 3120 are disposed inside the rotation frame 3140 facing each other. The X-ray generation unit 3110 and the X-ray detection unit 3120 can rotate in tandem with the rotation frame 3140.

The high voltage generation device 3150 includes a booster circuit, and outputs high voltage to the X-ray generation unit 3110. The DAS 3151 includes an amplification circuit and an A/D conversion circuit, and outputs the signal from the X-ray detection unit 3120 to the signal processing unit 3152 as digital data.

The signal processing unit 3152 includes a central processing unit (CPU), a read only memory (ROM) and a random access memory (RAM), and can execute image processing on digital data. The display unit 3153 includes a flat display device and the like, and can display an X-ray image. The control unit 3154 includes a CPU, ROM, RAM and the like, and controls operation of the X-ray CT device 3100 in general.

### Embodiment 17

A photoelectric conversion system according to Embodiment 17 will be described with reference to FIG. 32. FIG. 32 is a block diagram depicting a general configuration of an imaging system SYS, which is the photoelectric conversion system according to Embodiment 17. The imaging system SYS includes at least the photoelectric conversion device according to any of the above embodiments, and a signal processing unit which processes a signal outputted from the photoelectric conversion device.

The imaging system SYS is a camera or an information terminal which includes an image capturing function. The imaging system SYS is constructed using an imaging device IS. The imaging device IS may further include a package PKG which houses an imaging device IC. The package PKG may include a base body to which the imaging device IC is fixed and a cover which faces the imaging device IC. The package PKG may include a connecting member (a member to connect a terminal disposed on the base body and a terminal disposed on the imaging device IC). The imaging device IS may include a plurality of imaging device ICs that are arrayed in a common package PKG. Further, the imaging device IS may include the imaging device IC and another semiconductor device IC that are stacked in a common package PKG.

The imaging system SYS may include an optical system OU (optical device) to form an image on the imaging device IS. The imaging system SYS includes at least one of a control device CU, a processing device PU, a display device DU and a storage device MU. The control device CU controls the imaging device IS, and the processing device PU processes a signal acquired from the imaging device IS. Further, the display device DU displays an image acquired from the imaging device IS, and the storage device MU stores an image acquired from the imaging device IS.

### Other

Various apparatuses have been described in the above embodiments, but the present invention may further include a mechanical device. The mechanical device in a camera can drive components of the optical system for zooming, focusing or performing shutter operation. The mechanical device in the camera can also move the photoelectric conversion device for a vibration prevention operation.

The apparatus may be a transporting apparatus, of a vehicle, a ship, an airborne body, and the like. The mechanical device in the transporting apparatus may be used as a moving device. The apparatus used as a transporting apparatus is suitable for transporting the photoelectric conversion device, or assisting and/or automating driving (operating) based on the image capturing function. The processing device for assisting and/or automating the driving (operating) can perform processing to operate the mechanical device as a mobile device, based on the information acquired by the photoelectric conversion device.

The embodiments described above can be changed as required within the scope of not departing from the technical spirit of the invention. The disclosed content of the present description includes not only the content stated in the description, but also all the matters that can be recognized from the present description and the drawings accompanying the present description. The disclosed content of the present description also includes a complementary set of concepts stated in the present description. In other words, if it is stated that A is larger than B in the present description, for example, it can be said that the present description discloses that “A is not larger than B” even if it is not stated that “A is not larger than B”. Because if it is stated that “A is larger than B”, it is premised that the case of “A is not larger than B”.

In the present description, such expressions as “A or B”, “at least one of A and B”, “at least one of A or/and B” and “one of A or/and B or more” may be used. In this case, all possible combinations of the listed items can be included unless specified otherwise. In other words, it is understood that the above expressions disclose all the cases: including at least one A, including at least one B, and including both at least one A and at least one B. This is applicable to a combination of three or more elements.

According to the present invention, a suitable structure of pixels can be provided in a configuration where a high sensitivity pixel and a low sensitivity pixel include an avalanche photodiode respectively.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-169516, filed on Sep. 29, 2023, which is hereby incorporated by reference herein in its entirety.

What is claimed is:

1. A photoelectric conversion device comprising:
a first pixel including a first avalanche photodiode;
a second pixel including a second avalanche photodiode; and
an isolating portion that isolates the first pixel and the second pixel, wherein
in a plan view, a distance from a center of the first pixel to the isolating portion is longer than a distance from a center of the second pixel to the isolating portion.

2. The photoelectric conversion device according to claim 1, wherein
the isolating portion is a first isolating portion that isolates a region of the first pixel on a side close to a light incident surface, and a region of the second pixel on a side close to the light incident surface,
the photoelectric conversion device further comprises a second isolating portion that isolates a region of the first pixel on a side distant from the light incident surface, and a region of the second pixel on a side distant from the light incident surface, and
in the plan view, a distance from the center of the second pixel to the second isolating portion is longer than the distance from the center of the second pixel to the first isolating portion.

3. The photoelectric conversion device according to claim 1, wherein
the isolating portion is a first isolating portion that isolates a region of the first pixel on a side close to a light incident surface, and a region of the second pixel on a side close to the light incident surface,
the photoelectric conversion device further comprises a second isolating portion that isolates a region of the first pixel on a side distant from the light incident surface, and a region of the second pixel on a side distant from the light incident surface, and
in the plan view, a distance from the center of the first pixel to the second isolating portion is substantially same as a distance from the center of the second pixel to the second isolating portion.

4. The photoelectric conversion device according to claim 1, wherein
the first avalanche photodiode includes a first conductivity type first semiconductor region,
the second avalanche photodiode includes a first conductivity type second semiconductor region, and
in the plan view, a distance from an edge of the first semiconductor region on the isolating portion side to the isolating portion is longer than a distance from an edge of the second semiconductor region on the isolating portion side to the isolating portion.

5. The photoelectric conversion device according to claim 2, wherein
a plurality of first pixels are disposed at substantially equal intervals in each of a first direction and a second direction which is vertical to the first direction,
a plurality of second pixels are disposed at substantially equal intervals in each of the first direction and the second direction, and
a plurality of second isolating portions are disposed at substantially equal intervals in each of a third direction which equally divides the first direction and the second direction into two, and a fourth direction which is vertical to the third direction respectively.

6. The photoelectric conversion device according to claim 3, wherein
in the plan view, a distance from a cathode electrode of the first pixel to an anode electrode of the first pixel is substantially same as a distance from a cathode electrode of the second pixel to an anode electrode of the second pixel.

7. The photoelectric conversion device according to claim 5, wherein
in each of the third direction and the fourth direction, a plurality of cathode electrodes corresponding to a plurality of pixels including the plurality of first pixels and the plurality of second pixels respectively are disposed at substantially equal intervals.

8. The photoelectric conversion device according to claim 7, wherein
the isolating portion isolates the plurality of pixels, and
in the plan view,
the second pixel is disposed substantially at a center of four first pixels arranged in two rows×two columns, and
the isolating portion surrounds the first pixel in a substantially octagonal shape and surrounds the second pixel by a substantially square shape that is formed by the four substantially octagonal shapes corresponding to the four first pixels respectively.

9. The photoelectric conversion device according to claim 8, further comprising a plurality of metal bondings, which correspond to the plurality of pixels respectively, on a side opposite a light incident surface, wherein
in the plan view, positions of the plurality of metal bondings are substantially same as positions of the plurality of cathode electrodes.

10. A photoelectric conversion device comprising a first pixel including a first avalanche photodiode, and a second pixel including a second avalanche photodiode, and being configured such that leakage of light from the first pixel to the second pixel is suppressed more strongly than leakage of light from the second pixel to the first pixel.

11. The photoelectric conversion device according to claim 10, further comprising an isolating portion that isolates the first pixel and the second pixel, wherein
in a plan view, a distance from a center of the first pixel to the isolating portion is longer than a distance from a center of the second pixel to the isolating portion.

12. The photoelectric conversion device according to claim 11, wherein
the first avalanche photodiode includes a first conductivity type first semiconductor region,
the second avalanche photodiode includes a first conductivity type second semiconductor region, and
in the plan view, a distance from an edge of the first semiconductor region on the isolating portion side to the isolating portion is longer than a distance from an edge of the second semiconductor region on the isolating portion side to the isolating portion.

13. The photoelectric conversion device according to claim 11, wherein
the isolating portion is a first isolating portion that isolates a region of the first pixel on a side close to a light incident surface, and a region of the second pixel on a side close to the light incident surface,
the photoelectric conversion device further comprises a second isolating portion that isolates a region of the first pixel on a side distant from the light incident surface, and a region of the second pixel on a side distant from the light incident surface, and
in the plan view, a distance from the center of the second pixel to the second isolating portion is longer than the distance from the center of the second pixel to the first isolating portion.

14. The photoelectric conversion device according to claim 13, wherein
in the plan view, a distance from the center of the first pixel to the second isolating portion is substantially same as a distance from the center of the second pixel to the second isolating portion.

15. The photoelectric conversion device according to claim 13, wherein
a plurality of first pixels are disposed at substantially equal intervals in each of a first direction and a second direction which is vertical to the first direction,
a plurality of second pixels are disposed at substantially equal intervals in each of the first direction and the second direction, and
a plurality of second isolating portions are disposed at substantially equal intervals in each of a third direction which equally divides the first direction and the second direction into two, and a fourth direction which is vertical to the third direction respectively.

16. The photoelectric conversion device according to claim 13, wherein
in the plan view, a distance from a cathode electrode of the first pixel to an anode electrode of the first pixel is substantially same as a distance from a cathode electrode of the second pixel to an anode electrode of the second pixel.

17. The photoelectric conversion device according to claim 11, wherein
a plurality of first pixels are disposed at substantially equal intervals in each of a first direction and a second direction which is vertical to the first direction,
a plurality of second pixels are disposed at substantially equal intervals in each of the first direction and the second direction, and
a plurality of cathode electrodes which correspond to a plurality of pixels including the plurality of first pixels and the plurality of second pixels respectively, are disposed at substantially equal intervals in each of a third direction which equally divides the first direction and the second direction into two, and a fourth direction which is vertical to the third direction respectively.

18. The photoelectric conversion device according to claim 17, wherein
the isolating portion isolates the plurality of pixels, and
in the plan view,
the second pixel is disposed substantially at a center of four first pixels arranged in two rows×two columns, and
the isolating portion surrounds the first pixel in a substantially octagonal shape and surrounds the second pixel by a substantially square shape that is formed by the four substantially octagonal shapes corresponding to the four first pixels respectively.

19. The photoelectric conversion device according to claim 18, further comprising a plurality of metal bondings, which correspond to the plurality of pixels respectively, on a side opposite a light incident surface, wherein
in the plan view, positions of the plurality of metal bondings are substantially same as positions of the plurality of cathode electrodes.

20. The photoelectric conversion device according to claim 10, wherein
a trench, which is not disposed in the second pixel, is disposed in the first pixel.

21. A photoelectric conversion device comprising:
a first pixel including a first avalanche photodiode; and
a second pixel including a second avalanche photodiode, wherein
a trench, which is not disposed in the second pixel, is disposed in the first pixel.

22. A photoelectric conversion system comprising:
the photoelectric conversion device according to claim 1; and
a signal processing unit which generates an image by using a signal outputted by the photoelectric conversion device.

23. A mobile body including the photoelectric conversion device according to claim 1, the mobile body comprising a control unit which controls movement of the mobile body by using a signal outputted by the photoelectric conversion device.

24. An apparatus comprising:
the photoelectric conversion device according to claim 1; and
at least one of
an optical device corresponding to the photoelectric conversion device,
a control device that controls the photoelectric conversion device,
a processing device that processes a signal outputted from the photoelectric conversion device,
a display device that displays information acquired by the photoelectric conversion device,
a storage device that stores information acquired by the photoelectric conversion device, and
a mechanical device that operates based on information acquired by the photoelectric conversion device.
